(19) United States
(12) Patent Application Publication
(10) Pub. No.: US 2022/0276011 A1
(43) Pub. Date: Sep. 1, 2022

(54) HEAT CONDUCTING SHEET AND ITS METHOD OF MANUFACTURE

(71) Applicants: SHOWA MARUTSUTSU COMPANY, LTD., Osaka-shi, Osaka (JP); AWA PAPER & TECHNOLOGICAL COMPANY, Inc., Tokushima-shi, Tokushima (JP)

(72) Inventors: Eiichi TOYA, Kawasaki-shi (JP); Koji MATSUI, Kamakura-shi (JP); Yuya TOYOKAWA, Tokushima-shi (JP); Kazuki SHIBATA, Tokushima-shi (JP); Katsuhiko KAGAWA, Osaka-shi (JP); Takayuki YAMAGUCHI, Osaka-shi (JP)

(73) Assignee: SHOWA MARUTSUTSU COMPANY, LTD., Osaka-shi, Osaka (JP)

(21) Appl. No.: 17/631,469

(22) PCT Filed: Jun. 25, 2020
(86) PCT No.: PCT/JP2020/025001

§ 371 Date: Jan. 29, 2022

(30) Foreign Application Priority Data
Jul. 31, 2019 (JP) 2019-140637

(51) Int. Cl. F28F 21/02; H01L 23/373

(52) U.S. Cl. CPC F28F 21/02; H01L 23/3735

(57) ABSTRACT

A heat conducting sheet has an overall sheet structure with a plurality of heat conducting regions. Each heat conducting region is continuous between the two primary surfaces of the heat conducting sheet, and connecting regions connect adjacent side-walls of the plurality of heat conducting regions stacked laterally between the primary surfaces. The heat conducting regions include vacancies. The connecting regions consist of material that includes flexible resin material and unfilled layers are formed in part of the connecting regions. Some of the resin material can ingress into part of heat conducting region vacancies. This structure can achieve a highly elastic and flexible heat conducting sheet due to vacancies in the heat conducting regions and unfilled layers in the connecting region.

### CROSS-REFERENCE TO RELATED APPLICATIONS

This application is the U.S. National Stage of International Application No. PCT/JP2020/025001, filed on Jun. 25, 2020, which claims priority to Japanese Patent Application No. 2019-140,637, filed on Jul. 31, 2019, the entire contents of both of which are incorporated herein by reference.

### BACKGROUND

The present invention relates to a heat conducting sheet and its method of manufacture.

In recent years, dissipation of heat from heat-generating components in electronic equipment, automotive headlights, automobile battery systems, etc. has become a critical issue. For example, heat generated by electronic parts such as computer central processing units (CPUs), graphics processing units (GPUs), smart-phone system on a chip (SoC), embedded digital signal processors (DSPs) and microcomputers, semiconductor components such as (power) transistors, light emitting diodes (LEDs), electroluminescence (EL) devices, and light-emitting components in liquid crystal systems, is on an increasing trend due to device miniaturization and high-level integration. Device and system malfunction as well as lifetime degradation are problems that can result from heat generation by these types of electronic parts, and demand for heat-dissipation strategies is increasing yearly.

Heat-dissipation strategies for these types of heat-generating components include the use of (forced) cooling fans, peltier devices, and heat-sinks such as metal-fin (heat radiating) heat-sinks. Thermal grease (heat-sink compound) has been applied to heat-generating component surfaces to make thermal connection and prevent insulating air-gap formation at the interfaces. However, grease in general does not have good thermal conductivity. Consequently, diamond grease, which contains relatively high thermal conductivity diamond material distributed within the grease, is also in use (e.g. refer to JP2017-530220 Å).

However, diamond grease is expensive. Further, even when diamond grease is employed, achieving sufficient thermal conductivity can be difficult.

One object of the present invention is to provide a heat conducting sheet and its method of manufacture wherein the heat conducting sheet has superior thermal conductivity and superior flexibility.

### SUMMARY

Heat conducting sheet for the first aspect of the present invention can be provided with a plurality of heat conducting regions with each region continuous between the two primary surfaces of the heat conducting sheet; and connecting regions that connect adjacent surfaces of the plurality of heat conducting regions laterally stacked (layered) between the primary surfaces; the heat conducting sheet has an overall sheet or thin-film structure; the heat conducting regions include vacancies (micro-gaps); the connecting regions are made of materials that include flexible resin material formed in part with unfilled layers; and some of the resin material can ingress partially into the heat conducting region vacancies. This structure can achieve a highly elastic and flexible heat conducting sheet due to vacancies in the heat conducting regions and unfilled layers in the connecting region while maintaining robust connection between adjacent heat conducting regions due to resin material ingress into some of the heat conducting region vacancies (even with unfilled layers formed between heat conducting regions).

In addition to the configuration described above, heat conducting sheet for the second aspect of the present invention can have thermal conductivity that satisfies the relation 1.5≤λ_{0.8}/λ_{0.2}≤3.5, where λ_{0.2} [W/m·K] is heat conducting sheet thermal conductivity in the thickness direction when surface pressure of 0.2 N/mm² is applied in the thickness direction and λ_{0.8} [W/m·K] is heat conducting sheet thermal conductivity in the thickness direction when surface pressure of 0.8 N/mm² is applied in the thickness direction.

In addition to either of the configurations described above, heat conducting sheet for the third aspect of the present invention can have unfilled layers in the connecting regions that occupy greater than or equal to 2% and less than or equal to 30% of the connecting region volume.

In addition to any of the configurations described above, heat conducting sheet for the fourth aspect of the present invention can have heat conducting regions formed from materials including flake graphite and resin fiber.

In addition to any of the configurations described above, heat conducting sheet for the fifth aspect of the present invention can have aramid fiber as the resin fiber.

In addition to any of the configurations described above, heat conducting sheet for the sixth aspect of the present invention can have expanded graphite as the graphite.

In addition to any of the configurations described above, heat conducting sheet for the seventh aspect of the present invention can have thermal conductivity in the thickness direction of the heat conducting sheet as measured by laser-flash method that is greater than or equal to 10 W/m·K and less than or equal to 200 W/m·K.

In addition to any of the configurations described above, heat conducting sheet for the eighth aspect of the present invention can have heat conducting region width in the lateral direction of the heat conducting sheet (in a direction parallel to the surface of the heat conducting sheet) that is greater than or equal to 50 μm and less than or equal to 300 μm.

In addition to any of the configurations described above, heat conducting sheet for the ninth aspect of the present invention can have heat conducting sheet thickness that is greater than or equal to 0.2 mm and less than or equal to 5 mm.

In addition to any of the configurations described above, heat conducting sheet for the tenth aspect of the present invention can have heat conducting sheet thickness that is greater than or equal to 0.1 mm and less than or equal to 5 mm when 0.2 N/mm² surface pressure of is applied in the thickness direction.

In addition to any of the configurations described above, heat conducting sheet for the eleventh aspect of the present invention can have heat conducting sheet surface roughness Ra that is greater than or equal to 0.1 μm and less than or equal to 100 μm.

In addition to any of the configurations described above, heat conducting sheet for the twelfth aspect of the present invention can have resin material that includes (toroidal) ring molecules, a first polymer with linear chain (string) molecules that combine with multiple ring molecules by threading through the rings, polyrotaxane that is first polymer with blocking end groups at both ends of the first polymer, and a second polymer; and the resin material can be polyrotaxane and second polymer linked via the ring molecules.

In addition to any of the configurations described above, heat conducting sheet for the thirteenth aspect of the present invention can have the angle between a normal (vector) to the surface of the heat conducting sheet and a normal (vector) to the heat conducting regions that is greater than or equal to 25° and less than or equal to 90°.

In addition to any of the configurations described above, heat conducting sheet for the fourteenth aspect of the present invention can have interfaces between the heat conducting regions and connecting regions formed as curved surfaces. In this structure, by laterally stacking curved surface heat conducting regions and connecting regions, the heat conducting sheet can deform more easily when pressure is applied in the thickness direction of the sheet. For example, when heat conducting sheet is put in contact with the surface of a heat-generating component, it can easily make intimate contact without forming gaps and attain high thermal conductivity.

In addition to any of the configurations described above, heat conducting sheet for the fifteenth aspect of the present invention can have different thicknesses for some of the laterally stacked (in a direction parallel to heat conducting sheet primary surfaces) heat conducting regions and connecting regions.

The method of manufacture of heat conducting sheet for the sixteenth aspect of the present invention is a method of stacking (layering) a plurality of heat conducting regions (in a lateral direction parallel to heat conducting sheet primary surfaces) with each region established continuously from one primary surface to the other primary surface. The method of manufacture can include a step to impregnate pre-form sheet that forms the heat conducting regions with uncured resin material; a step to roll the uncured resin material impregnated pre-form sheet into a (cylindrical) roll; a step to cure (harden) the uncured resin material with the sheet wound in roll form; and a step to cut the rolled sheet with cured resin material along planes perpendicular to, parallel to, or on an incline to the axis of the roll. By winding the uncured resin material impregnated pre-form sheet into a (cylindrical) roll, the stacked layer configuration can be easily achieved. Further, by winding the sheet into a (cylindrical) roll, subsequent cutting and handling can be performed with ease to obtain low-cost heat conducting sheet.

In addition to the method of manufacture described above, the method of manufacture of heat conducting sheet for the seventeenth aspect of the present invention can further include a step to prepare heat conducting region pre-form sheet as a wound (cylindrical) roll prior to the step to impregnate heat conducting region pre-form sheet with uncured resin material. In this manner, pre-winding the heat conducting region pre-form sheet into a (cylindrical) roll and re-winding that sheet into a different roll after resin material impregnation makes it possible to efficiently impregnate resin material in a confined space even when the heat conducting region pre-form sheet is prepared in the form of a long sheet. Compared to a method that prepares numerous pre-cut rectangular heat conducting region pre-form sheets and impregnates those sheets with resin material, this (rolled sheet) method has the advantage of improving manufacturing efficiency.

In addition to either of the methods of manufacture described above, the method of manufacture of heat conducting sheet for the eighteenth aspect of the present invention can use thermosetting (heat-hardening) resin as the uncured resin material. This makes it possible to easily cure the thermosetting resin material via heat application even after sheet impregnation and winding into (cylindrical) roll form, and this has the positive feature that manufacturing efficiency is improved.

### BRIEF DESCRIPTION OF THE DRAWINGS

FIG. 1 is a schematic cross-section showing a heat-generating component and heat-sink employing the heat conducting sheet of the first embodiment of the present invention.

FIG. 2 is a schematic planar view with one region enlarged showing heat conducting sheet for the first embodiment of the present invention.

FIG. 3 is a schematic oblique view with one region enlarged showing heat conducting sheet for the first embodiment of the present invention.

FIG. 4 is a schematic side view showing heat conducting sheet for the first embodiment of the present invention.

FIG. 5A-5B are conceptual diagrams of an example of resin material that forms the connecting regions.

FIG. 6 is a schematic oblique view with one region enlarged showing heat conducting sheet for the second embodiment.

FIG. 7 is a schematic side view showing heat conducting sheet for the second embodiment.

FIG. 8 is a schematic planar view showing heat conducting sheet for the third embodiment.

FIG. 9A-9C are schematic cross-sections illustrating a method of manufacturing heat conducting sheet for the first embodiment.

FIG. 10 is a schematic cross-section illustrating another example of the layering (stacking) process to make heat conducting sheet for the first embodiment.

FIG. 11 is a schematic cross-section illustrating another example of the layering (stacking) process to make heat conducting sheet for the first embodiment.

FIG. 12A-12D are schematic cross-sections illustrating a method of manufacturing heat conducting sheet for the second embodiment.

FIG. 13A-13B are vertical cross-sections schematically illustrating change in heat conducting sheet thickness and heat conducting region inclination before and after the pressing process to make heat conducting sheet for the second embodiment.

FIG. 14A-14D are schematic cross-sections illustrating a method of manufacturing heat conducting sheet for the third embodiment.

FIG. 15 is a schematic diagram illustrating a method of manufacturing heat conducting sheet for the fourth embodiment.

FIG. 16 is a schematic cross-section showing curing of resin material in the rolled sheet of FIG. 15.

FIG. 17 is a schematic oblique view showing cutting locations on the rolled sheet.

FIG. 18 is a schematic oblique view showing another example of cutting locations on the rolled sheet.

FIG. 19A-19C are schematic cross-sections showing further examples of cutting locations on the rolled sheet.

FIG. 20 is an enlarged cross-section photograph of heat conducting sheet for the fourth embodiment.

FIG. 21 is an enlarged cross-section photograph of heat conducting sheet for the first embodiment.

FIG. 22 is an enlarged cross-section photograph of principal parts of the heat conducting sheet for the first embodiment.

FIG. 23 is an enlarged cross-section photograph of principal parts of FIG. 22.

### DESCRIPTION

The following describes embodiments of the present invention based on the figures. However, the following embodiments are merely specific examples of the heat conducting sheet and its method of manufacture representative of the technology associated with the present invention, and the heat conducting sheet and its method of manufacture of the present invention are not limited to the embodiments and implementations described below. Further, components described in the claims of this application are in no way limited to the components of the embodiments. Particularly, in the absence of specific annotation, structural component features described in the embodiments such as dimensions, raw material, shape, and relative position are simply for the purpose of explicative example and are not intended to limit the scope of the invention. Properties such as the size and spatial relation of components shown in the figures may be exaggerated for the purpose of clear explanation. In the descriptions following, components with the same name and reference number (sign) indicate components that are the same or have the same properties and their detailed description is appropriately abbreviated. Further, a single component can serve multiple functions and a plurality of structural elements of the invention can be implemented with the same component. In contrast, the functions of a single component can also be separated and implemented by a plurality of components.

### First Embodiment

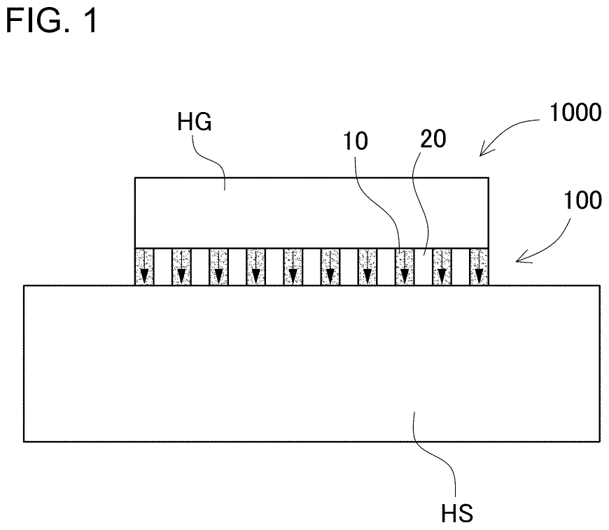

Heat conducting sheet can be used as a heat dissipating element for various heat-generating components. Preferred examples of heat-generating components include computational devices such as central processing units (CPUs), graphics processing units (GPUs), digital signal processors (DSPs), and microcomputers; driving devices such as transistors; light-emitting devices such as light emitting diodes (LEDs), organic light emitting diodes (O-LEDs), and liquid crystal systems; light sources such as halogen lamps; and driving units such as electric motors. The following describes an example of heat conducting sheet applied to a CPU as the first embodiment. Here, as shown in the schematic cross-section of FIG. 1, the CPU, which is the heat-generating component HG, cooling-fins, which are the heat-sink HS, and heat conducting sheet 100 between those elements form a thermally coupled heat dissipating unit 1000.

### (Heat Conducting Sheet 100)

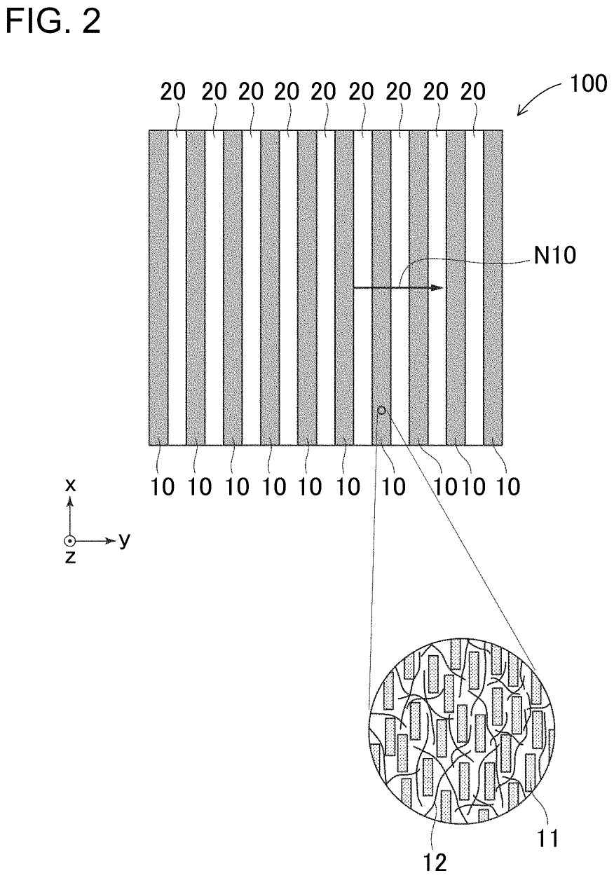

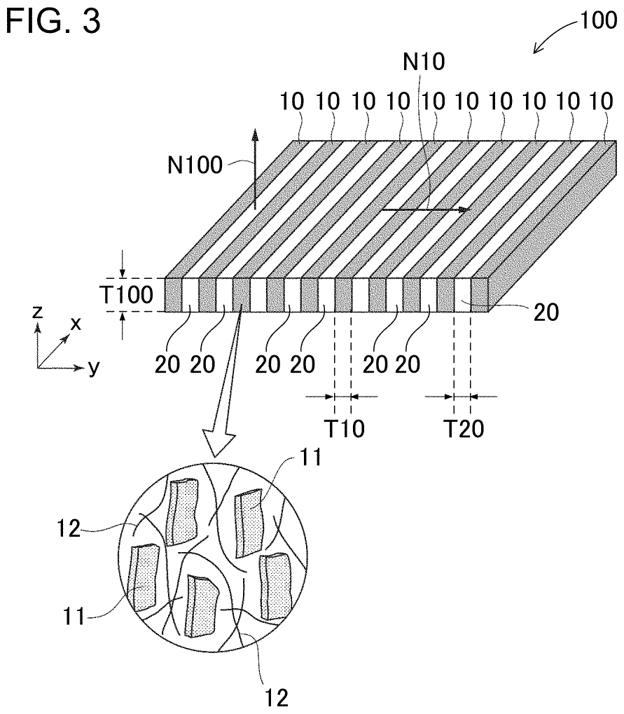

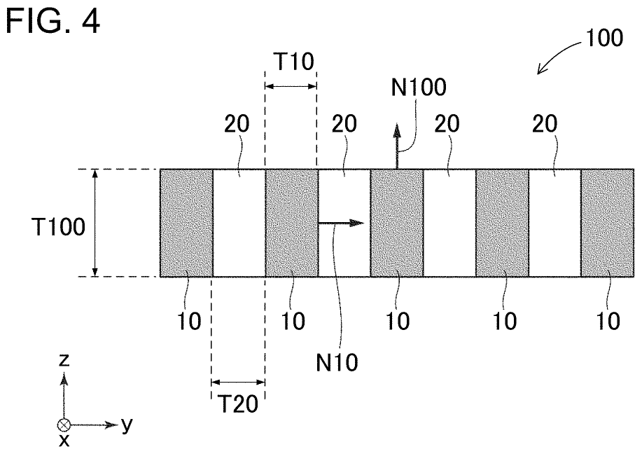

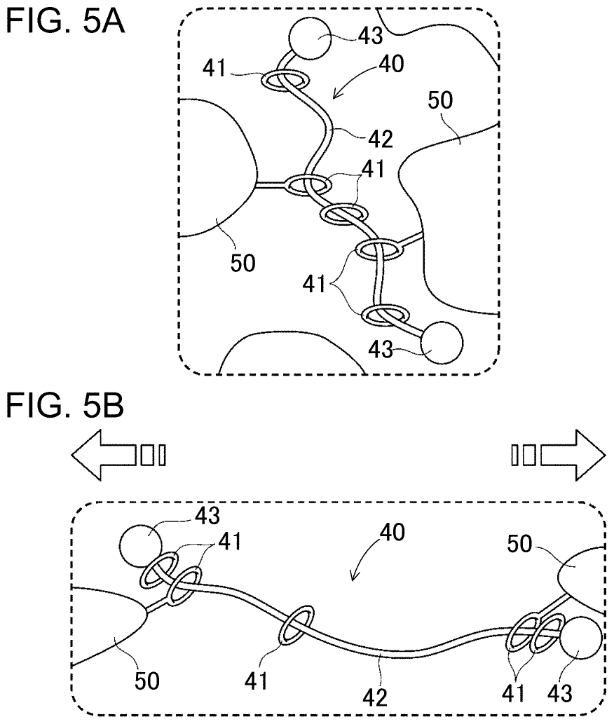

First, the heat conducting sheet 100 for the first embodiment is described based on FIGS. 2-4. FIG. 2 is a schematic planar view showing heat conducting sheet 100 for the first embodiment, FIG. 3 is a schematic oblique view showing the heat conducting sheet 100, and FIG. 4 is a schematic side view showing the heat conducting sheet 100. FIG. 5 shows conceptual diagrams for one example of resin material that forms the connecting regions.

As shown in FIGS. 2-4, heat conducting sheet 100 for the first embodiment is provided with a plurality of layered heat conducting regions 10 and connecting regions 20 that connect with each heat conducting region 10. The heat conducting sheet 100 has an overall sheet form. The heat conducting regions 10 are made of material that includes flake graphite 11 and resin fiber 12, and each heat conducting region 10 extends from one primary surface of the heat conducting sheet 100 to the other primary surface. Namely, each heat conducting region is exposed at primary surfaces on both sides of the heat conducting sheet 100. The connecting regions 20 are made of resin material that has flexibility. Graphite flakes (platelets) 11 are oriented with the thickness direction aligned with the direction of the thickness T10 of the layered heat conducting regions 10. The heat conducting sheet 100 for the present embodiment has a normal (vector) that forms an angle θ₁ with normal (vectors) to the heat conducting regions 10 which is greater than or equal to 25° and less than or equal to 90°.

Specifically, when a coordinate system is established with an orthogonal x-axis and y-axis in the plane of the heat conducting sheet 100 surface and a z-axis mutually orthogonal to the x-axis and y-axis, the heat conducting sheet 100 is provided with a plurality of heat conducting regions 10 extending in the x-direction and connecting regions 20 made of flexible resin material that connect the heat conducting regions 10 in the y-direction. Each heat conducting region 10 is composed of material that includes a plurality of graphite flakes (platelets) 11 and resin fiber 12, and graphite flakes (platelets) 11 in the heat conducting region 10 are oriented with the thickness direction in line with the y-axis.

Said differently, the heat conducting sheet 100 for the present embodiment preferentially transfers heat in a first direction which is in the direction of heat conducting sheet 100 thickness T100. The heat conducting sheet 100 and is provided with a plurality of heat conducting regions 10 that extend in a second direction perpendicular to the first direction, and connecting regions 20 made of flexible resin material that connect with each heat conducting region 10 in a third direction that is mutually perpendicular to the first and second directions. Each heat conducting region 10 is composed of material that includes resin fiber 12 and graphite 11 in the form of flakes (platelets) oriented with flake (platelet) thickness direction in the third direction.

Compared with thermal conductivity in a direction within the plane of the heat conducting sheet 100 (e.g. along the y-axis), thermal conductivity is higher in the sheet thickness direction (along the z-axis), and this configuration of heat conducting sheet 100 preferentially transfers heat in the z-axis direction (sheet thickness direction). Overall, this configuration can realize heat conducting sheet 100 with superior thermal conductivity in the thickness direction as well as exceptional flexibility. As a result, the heat conducting sheet 100 can, for example, conform ideally to the surface of a heat-generating component HG and can transfer and dissipate heat from that component in a preferred manner. More specifically, adhesion to the heat-generating component HG can be improved and thermal conductivity degradation due to residual air gaps can be effectively prevented. In particular, since the heat conducting sheet 100 has excellent thermal conductivity in the thickness direction, contact surface area with the heat-generating component HG can be large and overall thermal conductivity and heat dissipation can be exceptional. Further, the heat conducting sheet 100 can conform in a preferable manner to the surface of a heat-generating component HG even with complex surface topology or large surface roughness to effectively exhibit the previously mentioned capabilities.

Achievement of these excellent effects is believed to result from the following. Namely, heat conducting regions 10 include flake graphite 11 as high thermal conductivity material, and those graphite 11 flakes (platelets) have a given orientation within the heat conducting regions 10. In addition, since the heat conducting regions 10 extend continuously from one primary surface of the heat conducting sheet 100 to the opposite primary surface, even when the amount of included flake graphite 11 is not extremely high, distance between graphite 11 flakes (platelets) in the thickness direction of the heat conducting sheet 100 can be small and the percentage of graphite flakes (platelets) 11 in mutual contact can be large. As a result, excellent thermal conductivity in the thickness direction can be achieved while maintaining sufficient flexibility.

Further, by providing connecting regions 20 made of flexible resin material in addition to the heat conducting regions 10, heat conducting sheet 100 flexibility can be made particularly significant. As a result of superior flexibility, the ability of the heat conducting sheet 100 to conform to the surface of a heat-generating component HG is improved, and even when the surface of the heat-generating component HG has complex topology or relatively large surface roughness, unintended gaps between the heat conducting sheet 100 and heat-generating component HG can be effectively prevented. Consequently, dissipation of heat from the heat-generating component HG can be accomplished in a preferred manner.

By including resin fiber in addition to flake graphite 11 in the heat conducting regions 10, even when the amount of flake graphite 11 included is relatively large, graphite flakes (platelets) 11 can be retained in a preferable manner within the heat conducting regions 10 while making heat conducting regions 10 and heat conducting sheet 100 having high overall flexibility.

In contrast, when the conditions described above are not met, satisfactory results cannot be obtained. For example, if the sheet is made with heat conducting regions only and no connecting regions, overall sheet flexibility is inadequate and depending on the shape and surface topology of the heat-generating component, the applied sheet may not exhibit sufficient thermal conductivity. A sheet made with connecting regions only and no heat conducting regions clearly has low thermal conductivity. When resin fiber is not included in the heat conducting regions, it is difficult to make overall sheet that has sufficiently high flexibility. Further, if minute layers of molten or dissolved resin are formed in the heat conducting regions instead of including resin fiber, it is also difficult to make overall sheet with sufficiently high flexibility. Clearly, if graphite is not included in the heat conducting regions, sheet with low thermal conductivity results. In addition, if the flakes (platelets) of graphite in the heat conducting regions are not oriented in the direction described above or do not have a specific orientation, it is difficult to make sheet with sufficiently high thermal conductivity in the thickness direction. Further, even if the sheet has heat conducting regions formed with material including flake graphite and resin fiber but the heat conducting regions do not extend from one primary surface to the other primary surface of the sheet or, for example, if heat conducting regions are exposed from the primary surface on one side of the sheet but not from the primary surface on the other side or exposed from neither primary surface, heat cannot be sufficiently dissipated from a heat-generating component in contact with the heat conducting sheet. In the case where standard graphite powder (e.g. spherical or irregular shaped particulate graphite) is used in place of flake graphite, it is also difficult to make sheet with sufficiently high thermal conductivity in the thickness direction. In addition, if the angle θ₁ between the normal (vector) to the sheet surface and the normal (vector) to the heat conducting regions is not within the previously described range, thermal conductivity in the thickness direction of the heat conducting sheet is insufficient and heat dissipation from a heat-generating component in contact with the heat conducting sheet is also insufficient.

It is sufficient for the majority of graphite flakes (platelets) 11 included in the heat conducting regions 10 to be oriented as described previously, and it is not necessary for all the graphite flakes (platelets) 11 to be oriented as previously described. Specifically, all the graphite flakes (platelets) 11 do not need to have their thickness direction aligned with the thickness direction of the heat conducting region 10 layers (i.e. along the y-axis as shown in FIGS. 3 and 4). In this case as well, properties described previously are sufficiently exhibited.

The percentage (as a fraction of the total population) of graphite flakes (platelets) 11 included in the heat conducting regions 10 having the previously described orientation is preferably greater than or equal to 50%, more preferably greater than or equal to 60%, and still more preferably greater than or equal to 70%.

Further, previously described alignment of the thickness direction (direction normal to flake surfaces) of the graphite flakes (platelets) 11 with the thickness direction (i.e. along the y-axis as shown in FIGS. 3 and 4) of the heat conducting region 10 layers does not mean perfect alignment. For example, it is sufficient for the angle θ between the thickness direction of the graphite flakes (platelets) 11 and the thickness direction of the heat conducting region layers 10 to be less than or equal to 20° and preferably less than or equal to 10°.

As previously described, the angle θ₁ between a normal (vector) to the heat conducting sheet 100 and normal (vectors) to the heat conducting regions 10 can be greater than or equal to 25° and less than or equal to 90°. Preferably the angle θ₁ is greater than or equal to 30° and less than or equal to 90°, more preferably greater than or equal to 35° and less than or equal to 90°, and still more preferably greater than or equal to 40° and less than or equal to 90°. As a result, properties described previously are clearly realized.

### (Heat Conducting Regions 10)

The heat conducting sheet 100 is provided with a plurality of heat conducting regions 10 established extending from the primary surface on one side of the heat conducting sheet to the primary surface on the other side of the sheet. In the present embodiment, each heat conducting region 10 also extends in the direction of the x-axis when the heat conducting sheet 100 is viewed from above (or below). The heat conducting regions 10 are primary contributors to overall thermal conductivity of the heat conducting sheet 100 (particularly in the thickness [z-axis] direction).

The heat conducting regions 10 include flake graphite 11 and resin fiber 12. This heat conducting region 10 configuration has internal air gaps (micro-gaps) between the graphite flake (platelets) 11 and resin fiber 12 material. Due to the ingress of some connecting region 20 material (described subsequently) into those micro-gaps, adhesion between heat conducting regions 10 and connecting regions 20 is improved and this can improve the durability of the heat conducting sheet 100. In addition, air in the micro-gaps is replaced with connecting region 20 material, and since the thermal conductivity of connecting region 20 material is greater than that of air, connecting region 20 material ingress contributes to further improving the thermal conductivity of the heat conducting sheet 100.

### (Flake Graphite 11)

The plurality of graphite flakes (platelets) 11 included in each heat conducting region 10 have a given orientation. Specifically, the graphite flakes (platelets) 11 are oriented with their thickness direction (direction normal to platelet surfaces) aligned with the thickness direction (i.e. the y-axis direction as shown in FIGS. 3 and 4) of the heat conducting region 10 layers.

This configuration results in heat conducting sheet 100 with exceptional thermal conductivity in thickness direction (z-axis direction).

In this disclosure, the graphite flakes (platelets) can be components that have a sufficiently large primary surface with respect to thickness. For example, the flakes can have a flat-plate shape or a curved surface plate shape (e.g. a fish-scale shape).

The numerical average flatness (average flatness) of the graphite flakes (platelets) 11 is preferably greater than or equal to 2, more preferably greater than or equal to 3 and less than or equal to 100, and still more preferably greater than or equal to 5 and less than or equal to 50.

Here, graphite flake (platelet) 11 flatness is the ratio (Ly/t), where Ly [μm] is platelet primary surface length in the shorter direction and t [μm] is platelet thickness. Graphite flake (platelet) 11 average flatness can be determined, for example, by scanning electron microscope observation that finds the numerical average flatness of one hundred arbitrarily selected graphite platelets. Average length Ly of the shorter dimension of graphite flake (platelet) 11 primary surfaces and average graphite flake (platelet) 11 thickness (described below) can be found in the same manner.

Average graphite flake (platelet) 11 primary surface length in the shorter direction Ly is preferably greater than or equal to 0.2 μm and less than or equal to 50 μm, more preferably greater than or equal to 0.3 μm and less than or equal to 30 μm, and still more preferably greater than or equal to 0.5 μm and less than or equal to 10 μm.

Although it is sufficient for the flake graphite 11 to be graphite in flake or platelet form, expanded graphite can be favorably employed as the flake graphite 11. This can further enhance heat conducting sheet 100 strength, reliability, and thermal conductivity.

Expanded graphite can be obtained from raw material graphite that has a layered crystalline structure. Inter-layer compounds are formed by oxidizing agent acid treatment, and after washing, inter-layer compounds are expanded via high temperature heat treatment.

Although there are no specific limitations on the type of raw material used to produce expanded graphite, for example, natural graphite, kish graphite, and particulate graphite that has a layered crystalline structure are candidate materials.

There are also no specific limitations on the type of oxidizing agent used, and for example, sulfuric acid, nitric acid, phosphoric acid, perchloric acid, chromic acid, permanganic acid, per-iodic acid, and hydrogen peroxide can be used.

Heat treatment temperature for expanding the layered graphite is preferably greater than or equal to 400° C. and less than or equal to 1000° C.

While the content percentage of flake graphite 11 within the heat conducting regions 10 is not specifically limited, flake graphite content is preferably greater than or equal to 10% by mass and less than or equal to 90% by mass, more preferably greater than or equal to 30% by mass and less than or equal to 85% by mass, and still more preferably greater than or equal to 50% by mass and less than or equal to 80% by mass.

In this manner, a high level of both thermal conductivity and flexibility can be attained in the heat conducting regions 10.

### (Resin Fiber 12)

Each heat conducting region 10 contains resin fiber 12. This allows the previously described flake graphite 11 to be properly retained within the heat conducting regions 10. Compared to establishing precision layers of resin, this resin fiber inclusion can have higher flexibility. In addition, when the heat conducting sheet 100 is distorted, adjacent graphite flakes (platelets) 11 can be retained in an appropriately contacting condition within the overall sheet.

Constituent material of the resin fiber 12 include, for example, polyesters such as polyethylene terephthalate (PET), polybutylene terephthalate, and polylactic acid; polyolefins such as polyethylene and polypropylene; polyamides including aromatic polyamides (aramid resins) such as poly-paraphenylene terephthalamide, and aliphatic polyamides such as nylon 6 and nylon 66; polyether ketones such as polyether ether ketone, acrylic resin, polyvinyl acetate, polyvinyl alcohol, polyphenylene sulfide, polyparaphenylene benzoxazole, polyimide, polycarbonate, polystyrene, acrylonitrile-butadiene-styrene system resins (ABS resins), polyvinyl chloride system resins (PVC resins), thermoplastic resins such as phenoxy resin, epoxy resin, phenol resin, melamine resin, thermosetting resins such as unsaturated polyester, copolymers of the monomer constituents of these resins (e.g. ethylene vinyl alcohol copolymer), modified resins (e.g. maleic acid modified resin), and polymer alloys. Any of the above constituent materials can be used individually or two or more constituent types can be used in combination.

Among these constituent materials, resin fiber 12 made of aramid resin is preferable. This can further enhance heat conducting region 10 strength and overall heat conducting sheet 100 robustness. It can also make heat conducting sheet 100 resistance to thermal degradation superior. In addition, unintended resin fiber 12 melting and deformation during heat conducting sheet 100 formation can be effectively prevented, and superior heat conducting sheet 100 flexibility can be achieved more reliably. The resin fibers 12 can also be a plurality of different constituent fibers.

Although not specifically limited, average length of the resin fibers 12 is preferably greater than or equal to 1.5 mm and less than or equal to 20 mm, more preferably greater than or equal to 2.0 mm and less than or equal to 18 mm, and still more preferably greater than or equal to 3.0 mm and less than or equal to 16 mm. This can more favorably retain graphite flakes (platelets) 11 within the heat conducting regions 10 and reliably prevent unintended graphite flake (platelet) 11 detachment (fall-out). As a result, heat conducting sheet 100 durability and reliability can be made even more exceptional, and heat conducting sheet 100 flexibility can be made even more superior.

For the heat conducting sheet of the present embodiment, average fiber length can be determined, for example, by scanning electron microscope observation that finds the numerical average length of one hundred arbitrarily selected fibers.

Average resin fiber 12 width (thickness) is preferably greater than or equal to 1.0 μm and less than or equal to 50 μm, more preferably greater than or equal to 2.0 μm and less than or equal to 40 μm, and still more preferably greater than or equal to 3.0 μm and less than or equal to 30 μm. This can more favorably retain graphite flakes (platelets) 11 within the heat conducting regions 10 and reliably prevent unintended graphite flake (platelet) 11 detachment (fall-out). As a result, heat conducting sheet 100 durability and reliability can be made even more exceptional, and heat conducting sheet 100 flexibility can be made even more superior.

For the heat conducting sheet of the present embodiment, average fiber width (thickness) can be determined, for example, by scanning electron microscope observation that finds the numerical average thickness of one hundred arbitrarily selected fibers.

While the percentage of resin fiber 12 content within the heat conducting regions 10 is not specifically limited, it is preferably greater than or equal to 7% by mass and less than or equal to 90% by mass, more preferably greater than or equal to 12% by mass and less than or equal to 70% by mass, and still more preferably greater than or equal to 18% by mass and less than or equal to 50% by mass. Consequently, an even higher level of both thermal conductivity and flexibility can be attained in the heat conducting regions 10.

Accordingly, an even higher level of both thermal conductivity and flexibility can be attained in the heat conducting regions 10.

### (Other Constituents)

The heat conducting regions 10 can include constituents other than those described above. Other possible constituents include, for example, binder, flocculant (coagulant), plasticizer, coloring, anti-oxidant, ultraviolet light absorbing agents, photo-stabilizer, softener, modifiers, corrosion inhibitors, filler, surface lubricants, anti-decomposition agents, thermal stability agents, lubricants, primer, anti-static agents, polymerization inhibitors, cross-linking agents, catalyst, leveling agents, thickening agents, dispersing agents, anti-aging agents, flame retardant, anti-hydrolysis agents, anti-corrosion agents, carbon fiber, carbon nano-tubes, carbon nano-fiber, cellulose nano-fiber, fullerenes, metal fiber, and metal particulates.

The thermal conductivity at 20° C. in the thickness direction of the heat conducting sheet 100 with heat conducting regions 10 as described above is preferably greater than or equal to 10 W/m·K and less than or equal to 200 W/m·K, more preferably greater than or equal to 15 W/m·K and less than or equal to 180 W/m·K, and still more preferably greater than or equal to 20 W/m·K and less than or equal to 160 W/m·K. Here, thermal conductivity of the heat conducting sheet for the present embodiment uses values computed in accordance with Japanese Industrial Standard (JIS) R1611 by measuring thermal diffusivity (mm²/sec) by the laser-flash method and finding the product of thermal diffusivity and heat capacity (density×specific heat).

While heat conducting region 10 thickness (heat conducting region thickness in the y-axis direction as shown in FIGS. 3 and 4) is not specifically limited, it is preferably greater than or equal to 50 μm and less than or equal to 300 μm, more preferably greater than or equal to 55 μm and less than or equal to 270 μm, and still more preferably greater than or equal to 60 μm and less than or equal to 250 μm. Accordingly, an even higher level of both thermal conductivity and flexibility can be attained in the heat conducting regions 10. In addition, heat conducting sheet 100 manufacturability can be more exceptional.

Thickness of the plurality of heat conducting regions 10 in the heat conducting sheet 100 can be uniform or the heat conducting regions 10 can have different thicknesses. When the heat conducting regions 10 have different thicknesses, the percentage of the total number of heat conducting regions within the heat conducting sheet that have thickness within the range described above is preferably greater than or equal to 50%, more preferably greater than or equal to 70%, and still more preferably greater than or equal to 90%.

The percent of the total volume of the heat conducting sheet 100 occupied by the heat conducting regions 10 is preferably greater than or equal to 30% by volume and less than or equal to 90% by volume, more preferably greater than or equal to 40% by volume and less than or equal to 85% by volume, and still more preferably greater than or equal to 50% by volume and less than or equal to 82% by volume. This allows a higher level of both thermal conductivity and flexibility to be attained in the heat conducting regions 10.

### (Connecting Regions 20)

The heat conducting sheet 100 is provided with a plurality of connecting regions 20 in contact with and joined to surfaces of the previously described heat conducting regions 10. In the present embodiment, connecting regions 20 extend in the x-axis direction.

While the heat conducting sheet 100 is provided with at least one connecting region 20, the configuration shown in the figures is provided with a plurality of connecting regions 20. More specifically, the heat conducting sheet 100 configuration shown in the figures has a plurality of connecting regions 20 as well as a plurality of heat conducting regions 10. Heat conducting regions 10 and connecting regions 20 alternate in the y-axis direction, and heat conducting regions 10 are disposed at both ends of the sheet in the y-axis direction. Namely, when the number of heat conducting regions 10 established in the heat conducting sheet 100 is (n), the number of connecting regions 20 is (n−1).

Connecting regions 20 are composed of resin material that has flexibility (pliability). Unfilled layers are formed in parts of the connecting regions 20. The unfilled layers contain air and gases evolved during resin material curing. In addition, some of the connecting region resin material ingresses into heat conducting region micro-gaps (vacancies). The fraction of the connecting regions occupied by unfilled layers is preferably greater than or equal to 2% by volume and less than or equal to 30% by volume.

### (Resin Material)

Resin material that forms the connecting regions 20 serves to link adjacent heat conducting regions 10. Connecting region 20 resin material has flexibility (elasticity). Accordingly, the heat conducting sheet 100 can easily conform to the surface topology of a heat-generating component HG for example. Consequently, the heat conducting sheet 100 can transfer and dissipate heat away from the heat-generating component HG in an ideal manner. Also when the heat conducting sheet 100 is distorted, sheet damage can be appropriately prevented.

Resin material in the connecting regions 20 is different than the previously described resin fiber 12 in the heat conducting regions 10, and is a sufficiently dense material. This type of connecting region 20 can be appropriately formed from the subsequently described liquid resin material 20′ or resin material 20′ in sheet form (sheet with the same composition as the liquid resin material).

While the type of resin material that forms the connecting regions 20 is not specifically limited, resins other than hard resin, for example, flexible epoxy resin, urethane system resins, rubber system resins, fluorine system resins, silicone system resins, and thermoplastic elastomers can be used advantageously.

In addition, as illustrated in FIG. 5, connecting region 20 resin material can include (toroidal) ring molecules 41, a first polymer 42 with linear chain (string) molecules that combine with the ring molecules 41 by threading through the rings, polyrotaxane 40 that has blocking end groups 43 established near both ends of the first polymer 42, and a second polymer 50. Preferably, the resin material is polyrotaxane 40 and second polymer 50 linked via the ring molecules 41.

Accordingly, bonding strength between adjacent heat conducting regions 10 via the connecting regions 20 as well as heat conducting sheet 100 durability can be sufficiently great, while heat conducting sheet 100 resistance to thermal degradation (e.g. ability to withstand use in a 200° C. environment) and flexibility can be particularly significant. In addition, this type of resin material makes it easy for resin to ingress into heat conducting region 10 micro-gaps (vacancies) during heat conducting sheet 100 fabrication. Consequently, this is beneficial for further improving heat conducting sheet 100 durability and thermal conductivity.

In particular, when stress is applied (in the direction of the arrows shown in FIG. 5B) to deform the (connecting region 20) resin material shown in FIG. 5A, that resin material can assume the form shown in FIG. 5B. Namely, since the ring molecules 41 can move along the first polymer 42 string (i.e. first polymer 42 string can move inside the ring molecules 41), deforming stress forces can be aptly absorbed within the resin material (inside the connecting regions 20). Consequently, even when large deformation force (e.g. external twisting force) is applied, connecting region 20 damage and detachment of connecting regions 20 from heat conducting regions 10, etc. can be effectively prevented.

The following describes in detail resin material containing polyrotaxane 40 and second polymer 50. While the ring molecule 41 components of polyrotaxane 40 are any molecules that can move along the first polymer 42 string, the ring molecule 41 are preferably cyclodextrin molecules that allow substitution. The cyclodextrin molecules are preferably selected from the group: α-cyclodextrin, β-cyclodextrin, γ-cyclodextrin, and their derivatives.

At least some of the ring molecules 41 in the polyrotaxane 40 bind with at least part of the previously described second polymer 50.

Ring molecules 41 functional groups (functional groups for bonding with the second polymer 50) can include, for example, —OH radical, —NH₂ group, —COOH group, epoxy group vinyl group, thiol group, and photo-cross-linking groups. As photo-cross-linking groups, for example, cinnamic acid, coumarin, chalcone, anthracene, styryl pyridine, styryl pyridinium salt, and styryl quinolinium chloride should be mentioned.

When the maximum amount of ring molecule 41 inclusion to form the ring and string (chain) structure with the first polymer 42 is taken to be 1, the amount of ring molecule 41 inclusion in the ring and string structure with first polymer 42 is preferably greater than or equal to 0.001 and less than or equal to 0.6, more preferably greater than or equal to 0.01 and less than or equal to 0.5, and still more preferably greater than or equal to 0.05 and less than or equal to 0.4.

Candidate materials for the first polymer 42 component in the polyrotaxane 40 include, for example, polyvinyl alcohol, polyvinyl pyrrolidone, poly (meta) acrylic acid, cellulose system resins (e.g. carboxymethyl-cellulose, hydroxyethyl-cellulose, hydroxypropyl-cellulose), polyacrylamide, polyethylene oxide, polyethylene glycol, polypropylene glycol, polyvinyl, polyvinyl acetal system resins, polyvinyl methyl ether, polyamine, polyethylenimine, casein, gelatin, starches and/or their copolymers, polyethylene, polypropylene, polyolefin system resins such as copolymers of other olefin system monomers, polyester resins, polyvinyl chloride resins, polystyrene system resins such as polystyrene and acrylonitrile-styrene copolymer resins, polymethyl methacrylate and (meth)acrylic acid ester copolymers, acrylic system resins such as acrylonitrile-methyl acrylate copolymer resin, polycarbonate resin, polyurethane resin, vinyl chloride-vinyl acetate copolymer resin, polyvinyl butyral resin and its derivatives or modified resins, polyisobutylene, polytetrahydrofuran, polyaniline, acrylonitrile-butadiene-styrene copolymers (ABS resins), polyamides such as nylon, polyimides, polyisoprene, polydienes such as polybutadiene, polysiloxanes such as polydimethylsiloxane, polysulfones, polyimines, polyacetic anhydrides, polyureas, polysulfides, polyphosphazenes, polyketones, polyphenylenes, polyhalo-olefins, and derivatives. In particular, polyethylene glycol is preferred.

The weight-average molecular weight of the first polymer 42 is preferably greater than or equal to 10000, more preferably greater than or equal to 20000, and still more preferably greater than or equal to 35000. Note that two or more different types of first polymer 42 can be used.

As paired-up first polymer 42 and ring molecules 41, the combination of polyethylene glycol as first polymer 42 and α-cyclodextrin that allows substitution as ring molecules 41 is preferred.

The blocking end groups 43 included in the polyrotaxane 40 structure can be any group or radical that can prevent separation of the ring molecules 41 from the first polymer 42, and otherwise have no particular restrictions. Blocking end groups 43 can be, for example, dinitrophenyl groups, cyclodextrins, adamantine groups, trityl groups, fluoresceine groups, pyrenes, substituted benzenes (where substituted groups include alkyl, alkyloxy, hydroxy, halogen, cyano, sulfonyl, carboxyl, amino, and phenyl groups; and one or a plurality of substitutions are possible), polynuclear aromatic systems that allow substitution, and steroids. Substitution groups for substituted benzenes and polynuclear aromatic systems that allow substitution include, for example, alkyl, alkyloxy, hydroxy, halogen, cyano, sulfonyl, carboxyl, amino, and phenyl groups. Configurations can have a single substitution group or a plurality of substitution groups. Note that two or more different types of blocking end groups 43 can be used.

Within the resin material in the connecting regions 20, at least some of the polyrotaxane 40 is bonded with second polymer 50 via ring molecules 41. However, resin material in the connecting regions 20 can include polyrotaxane 40 that is not bonded to second polymer 50, and polyrotaxane 40 can also bond with other polyrotaxane 40.

Second polymer 50 is material that bonds with polyrotaxane 40 via the ring molecules 41. Second polymer 50 functional groups that bond with ring molecules 41 include, for example, —OH radical, —NH₂ group, —COOH group, epoxy group vinyl group, thiol group, and photo-cross-linking functional groups. As photo-cross-linking groups, for example, cinnamic acid, coumarin, chalcone, anthracene, styryl pyridine, styryl pyridinium salt, and styryl quinolinium chloride are mentioned.

Candidate materials for the second polymer 50 include, for example, polyvinyl alcohol, polyvinyl pyrrolidone, poly (meta) acrylic acid, cellulose system resins (e.g. carboxymethyl-cellulose, hydroxyethyl-cellulose, hydroxypropyl-cellulose), polyacrylamide, polyethylene oxide, polyethylene glycol, polypropylene glycol, polyvinyl, polyvinyl acetal system resins, polyvinyl methyl ether, polyamine, polyethylenimine, casein, gelatin, starches and/or their copolymers, polyethylene, polypropylene, polyolefin system resins such as copolymers of other olefin system monomers, polyester resins, polyvinyl chloride resins, polystyrene system resins such as polystyrene and acrylonitrile-styrene copolymer resins, polymethyl methacrylate and (meth)acrylic acid ester copolymer, acrylic system resins such as acrylonitrile-methyl acrylate copolymer resin, polycarbonate resin, polyurethane resin, vinyl chloride-vinyl acetate copolymer resin, polyvinyl butyral resin and its derivatives or modified resins, polyisobutylene, polytetrahydrofuran, polyaniline, acrylonitrile-butadiene-styrene copolymer (ABS resin), polyamides such as nylon, polyimides, polyisoprene, polydienes such as polybutadiene, polysiloxanes such as polydimethylsiloxane, polysulfones, polyimines, polyacetic anhydrides, polyureas, polysulfides, polyphosphazenes, polyketones, polyphenylenes, polyhalo-olefins and configurations having the skeletal structures of those resins with the previously described functional groups.

It is also possible for the second polymer 50 and ring molecules 41 to be chemically bonded via cross-linking agents.

Molecular weight of the cross-linking agent is preferably less than 2000, more preferably less than 1000, still more preferably less than 600, and most preferably less than 400.

Cross-linking agents include, for example, cyanuric chloride, trimesoyl chloride, terephthaloyl-chloride, epichlorohydrin, dibromobenzene, glutaraldehyde, phenylene diisocyanate, tolylene diisocyanate, divinyl sulfone, 1,1′-carbonyldiimidazole, and alkoxysilane. Note that two or more different types of cross-linking agents can be used.

In addition, the second polymer 50 can be either homopolymer or copolymer. Within the resin material in the connecting regions 20, at least some of the second polymer 50 is bonded with polyrotaxane 40 via ring molecules 41. However, resin material in the connecting regions 20 can include second polymer 50 that is not bonded to polyrotaxane 40, and second polymer 50 can also bond with other second polymer 50. Note that two or more different types of second polymer 50 can be used.

The ratio of the weight content of polyrotaxane 40 to the weight content of second polymer 50 in the connecting region 20 resin material is preferably greater than or equal to 1/1000.

### (Other Constituents)

Connecting regions 20 can also include constituents other than those mentioned above. Those other constituents include, for example, plasticizer, coloring, anti-oxidant, ultraviolet light absorbing agents, photo-stabilizer, softener, modifiers, corrosion inhibitors, filler, surface lubricants, anti-decomposition agents, thermal stability agents, lubricants, primer, anti-static agents, polymerization inhibitors, cross-linking agents, catalyst, leveling agents, thickening agents, dispersing agents, anti-aging agents, flame retardant, anti-hydrolysis agents, and anti-corrosion agents.

The heat conducting sheet 100 of the present embodiment is a laterally stacked structure. Connecting region 20 thickness T20 (lateral connecting region layer thickness in the y-axis direction of FIGS. 3 and 4) is not specifically limited, but connecting region thickness T20 is preferably greater than or equal to 0.1 μm and less than or equal to 200 μm, more preferably greater than or equal to 0.1 μm and less than or equal to 100 μm, and still more preferably greater than or equal to 0.1 μm and less than or equal to 50 μm. Accordingly, an even higher level of both thermal conductivity and flexibility can be attained in the heat conducting regions 10. In addition, heat conducting sheet 100 manufacturability can be more superior.

When the heat conducting sheet 100 has a plurality of connecting regions 20, thickness of the connecting regions 20 can be uniform or the connecting regions 20 can have different thicknesses. When the connecting regions 20 have different thicknesses, the percentage of the total number of connecting regions within the heat conducting sheet that have thickness within the range described above is preferably greater than or equal to 50%, more preferably greater than or equal to 70%, and still more preferably greater than or equal to 90%.

Although heat conducting regions 10 and connecting regions 20 are illustrated in the figures as being coplanar in both primary surfaces of the heat conducting sheet 100, heat conducting sheet 100 thickness T100 can actually be different in regions where heat conducting regions 10 are established and in regions where connecting regions 20 are established. For example, although the figures illustrate heat conducting sheet 100 configurations with each connecting region 20 exposed from both primary surfaces, at least one of the connecting regions 20 may be exposed from only one of the heat conducting sheet 100 primary surfaces, or may not be exposed from either of the heat conducting sheet 100 primary surfaces.

The percent of the total volume of the heat conducting sheet 100 occupied by the connecting regions 20 is preferably greater than or equal to 10% by volume and less than or equal to 70% by volume, more preferably greater than or equal to 15% by volume and less than or equal to 60% by volume, and still more preferably greater than or equal to 18% by volume and less than or equal to 50% by volume. This allows a higher level of both thermal conductivity and flexibility to be attained.

While configurations illustrated in the figures show clear boundaries between heat conducting regions 10 and connecting regions 20, those boundaries may actually be indistinct due to constituent material diffusion and miscibility, etc. on at least one side of the heat conducting region 10-connecting region 20 interface. Even in this case, distinction between heat conducting regions 10 and connecting regions 20 is possible because heat conducting regions 10 are areas where flake graphite 11 and resin fiber 12 content is higher than in the connecting regions 20, and connecting regions 20 are areas where the content of (above described) resin material that makes up the connecting regions 20 is higher than the content of (previously described) resin material within the heat conducting regions 10.

While heat conducting sheet 100 applications have no particular limitations, the heat conducting sheet 100 can be used, for example, in various heat dissipating sheet applications.

Heat conducting sheet 100 thickness T100 (in the z-axis direction) is preferably greater than or equal to 0.2 mm and less than or equal to 5 mm, more preferably greater than or equal to 0.3 mm and less than or equal to 4 mm, and still more preferably greater than or equal to 0.5 mm and less than or equal to 3 mm. This allows the heat conducting sheet 100 to easily conform to the surface topology of a heat-generating component HG for ideal thermal conduction and heat dissipation. Further, the heat conducting sheet 100 can attain a high level of both thermal conductivity and flexibility.

Surface roughness Ra of both primary surfaces of the heat conducting sheet 100 is preferably greater than or equal to 0.1 μm and less than or equal to 100 μm, more preferably greater than or equal to 0.2 μm and less than or equal to 80 μm, and still more preferably greater than or equal to 0.3 μm and less than or equal to 60 μm. This can prevent significant reduction in manufacturability, and enables the sheet to effectively conform to the surface topology of a heat-generating component HG for ideal thermal conduction and heat dissipation.

Heat conducting sheet 100 surface roughness Ra can be measured, for example, in accordance with Japanese Industrial Standard (JIS) B0601-2013 specifications. In addition, heat conducting sheet 100 surface roughness Ra can be adjusted by surface polishing.

### (Heat Conducting Sheet 100 Thermal Conductivity in the Thickness Direction)

When surface pressure of 0.2 N/mm² is applied in the thickness direction of the heat conducting sheet 100, thermal conductivity in the thickness direction is measured as λ_{0.2} [W/m·K], and when surface pressure of 0.8 N/mm² is applied in the thickness direction of the heat conducting sheet 100, thermal conductivity in the thickness direction is measured as λ_{0.8} [W/m·K]. Under those conditions, thermal conductivity preferably satisfies the relation 1.5≤λ_{0.8}/λ_{0.2}≤3.5, more preferably satisfies the relation 1.7≤λ_{0.8}/λ_{0.2}≤3.2, and still more preferably satisfies the relation 1.9≤λ_{0.8}/λ_{0.2}≤3.0.

If the λ_{0.8}/λ_{0.2} ratio is too small, depending on conditions between the heat conducting sheet and materials contacted by the sheet, intimate contact between the heat conducting sheet and a heat-generating component HG may be insufficient and there is a possibility that sufficient thermal conduction may not be realized. In contrast If the λ_{0.8}/λ_{0.2} ratio is too large, structural integrity is diminished, heat conducting sheet durability is degraded, and large lot-to-lot variation resulting in inability to maintain stable sheet functionality are concerns. Accordingly, it is desirable to keep the λ_{0.8}/λ_{0.2} ratio within the range described above.

Heat conducting sheet 100 thermal conductivity in the thickness direction measured by the laser-flash method at primary surfaces is preferably greater than or equal to 10 W/m·K and less than or equal to 200 W/m·K, more preferably greater than or equal to 15 W/m·K and less than or equal to 180 W/m·K, and still more preferably greater than or equal to 20 W/m·K and less than or equal to 160 W/m·K.

This results in heat conducting sheet with high thermal conductivity, and achieves the effects that heat can be transferred and dissipated in a more preferred manner.

When surface pressure of 0.2 N/mm² is applied in the thickness direction of the heat conducting sheet 100, heat conducting sheet 100 thickness preferably becomes greater than or equal to 0.1 mm and less than or equal to 5 mm, more preferably becomes greater than or equal to 0.2 mm and less than or equal to 4 mm, and still more preferably becomes greater than or equal to 0.3 mm and less than or equal to 3 mm.

This insures highly conformable heat conducting sheet having thickness that absorbs depressions and protrusions in heat-generating components HG and heat sink surfaces to restrain interfacial thermal resistance and achieve the effects of transferring and dissipating heat in a more preferred manner.

### Second Embodiment

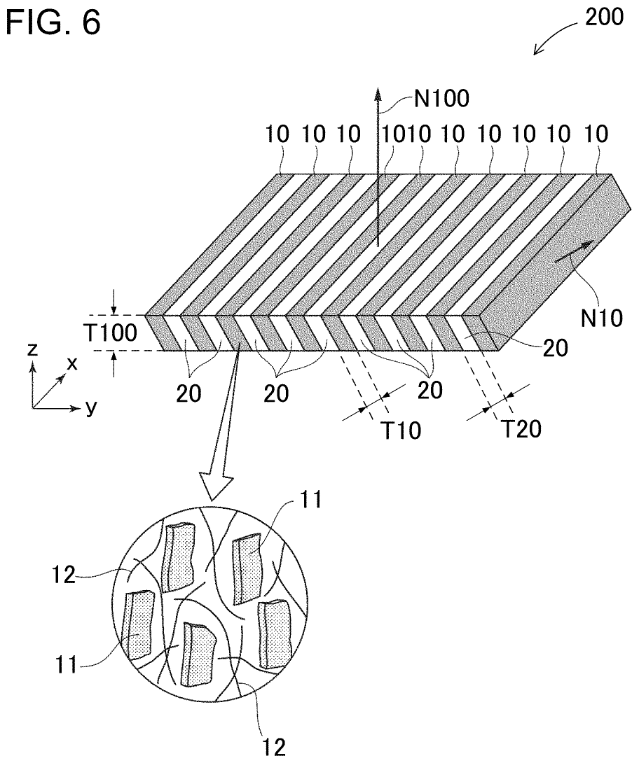

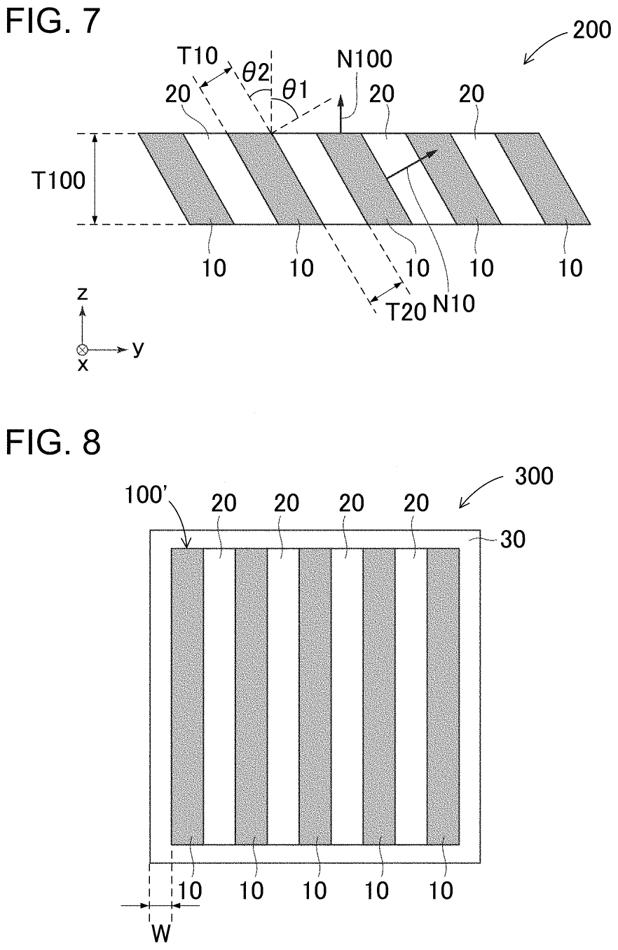

Next, heat conducting sheet for the second embodiment is described based on FIGS. 6 and 7. Here, FIG. 6 is a schematic oblique view of the heat conducting sheet 200 for the second embodiment, and FIG. 7 is a schematic side view of the heat conducting sheet 200 for the second embodiment. The following description focuses on differences between the first and second embodiments, and description of like items is suitably abbreviated.

In the previously described first embodiment, the normal (vector) N100 to the heat conducting sheet 100 and normal (vectors) to the heat conducting regions 10 were perpendicular (90° angle between normal vectors). In contrast, heat conducting sheet 200 for the second embodiment has a normal (vector) N100 that is not perpendicular to the normal (vectors) to the heat conducting regions 10. Accordingly, heat conducting sheet 200 in this embodiment can have an angle θ₁ between the heat conducting sheet 200 normal (vector) N100 and heat conducting region 10 normal (vectors) that is preferably greater than or equal to 25° and less than or equal to 90°, and there is no requirement for the heat conducting sheet 200 normal (vector) N100 and heat conducting region 10 normal (vectors) to be perpendicular. In this case as well, the previously described (beneficial) effects are realized.

In addition, by not making the heat conducting sheet 200 normal (vector) N100 and the heat conducting region 10 normal (vectors) orthogonal, heat conducting sheet 200 durability with respect to pressure applied in the thickness direction is improved. This is because when the heat conducting sheet normal N100 is orthogonal to heat conducting region 10 normals and pressure is applied in the sheet thickness direction, heat conducting regions 10 and connecting regions 20 can readily delaminate as a result of heat conducting region 10 buckling due to heat conducting region 10 and connecting region 20 differences in properties such as rigidity. In contrast, when the heat conducting sheet 200 normal N100 is not perpendicular to heat conducting region 10 normals and pressure is applied in the sheet thickness direction, the pressure force has a component in a direction that presses the heat conducting regions 10 and connecting regions 20 together, and that component force is believed to contribute to improving adhesion between the heat conducting regions 10 and connecting regions 20.

In the case of the present embodiment where the normal (vector) N100 to the heat conducting sheet 200 is not perpendicular to the normal (vectors) to the heat conducting regions 10, the angle θ₁ between a normal (vector) to the heat conducting sheet 200 and normal (vectors) to the heat conducting regions 10 is preferably greater than or equal to 30° and less than or equal to 85°, more preferably greater than or equal to 35° and less than or equal to 80°, and still more preferably greater than or equal to 40° and less than or equal to 75°. This enables marked display of the previously described properties.

### Third Embodiment

Next, heat conducting sheet for the third embodiment is described based on FIG. 8. FIG. 8 is a schematic planar view showing heat conducting sheet 300 for the third embodiment. The following description focuses on differences between the previously described embodiments, and description of like items is appropriately abbreviated.

Heat conducting sheet 300 for the third embodiment is provided with a main sheet body 100′ having the same structure as the heat conducting sheet 100 for previously described embodiment, and a frame 30 established in contact with the perimeter of the main sheet body 100′. Namely, except for the frame 30, this heat conducting sheet 300 has the same structure as the previously described embodiment.

This heat conducting sheet 300 can aptly prevent sheet damage even in cases where the junction strength between heat conducting regions 10 and connecting regions 20 is relatively low, where the inherent strength of the heat conducting regions 10 is low, and where the inherent strength of the connecting regions 20 is low. In particular, when the heat conducting sheet 300 is applied to conform to the surface of a heat-generating component HG, damage to the heat conducting sheet 300 can be effectively prevented even when the sheet is subject to relatively large deformation. In addition, during heat conducting sheet 300 manufacture, unintended sheet deformation can be effectively prevented allowing heat conducting sheet 300 of the desired shape to be more readily manufactured. In particular, thin heat conducting sheet 300 having relatively small thickness (in the z-axis direction) can be manufactured in a more straightforward manner.

Constituent material for the frame 30 can be, for example, resin materials including polyethylene, polypropylene, polyolefins such as polymethyl pentene, polyvinyl chloride, polyvinylidene chloride (PVDC), polyesters such as polyethylene terephthalate (PET), and copolymers of those resins, as well as metals including aluminum, copper, iron, and stainless steel. While any of these candidate materials or a combination of two or more of those materials can be used, polyvinylidene chloride is particularly desirable. Since polyvinylidene chloride has particularly good adhesion to various other resin materials as well as good self-adhesion, unintended separation from the main sheet body 100′ can be effectively prevented, and the previously described properties can be more readily apparent. Further, since polyvinylidene chloride has a high tensile modulus of elasticity, ease of handling during heat conducting sheet 300 manufacture is particularly outstanding.

The width W of the frame 30 is preferably greater than or equal to 3 μm and less than or equal to 2000 μm, more preferably greater than or equal to 5 μm and less than or equal to 1500 μm, and still more preferably greater than or equal to 30 μm and less than or equal to 1000 μm. This makes heat conducting sheet 300 flexibility sufficiently great, and significantly demonstrates the effects of frame 30 inclusion. Note that frame 30 width W can be uniform on all sides of the sheet or the width W can vary with location.

While frame 30 thickness (in the z-axis direction) is not specifically limited, it is preferably greater than or equal to 0.2 mm and less than or equal to 5 mm, more preferably greater than or equal to 0.3 mm and less than or equal to 4 mm, and still more preferably greater than or equal to 0.5 mm and less than or equal to 3 mm.

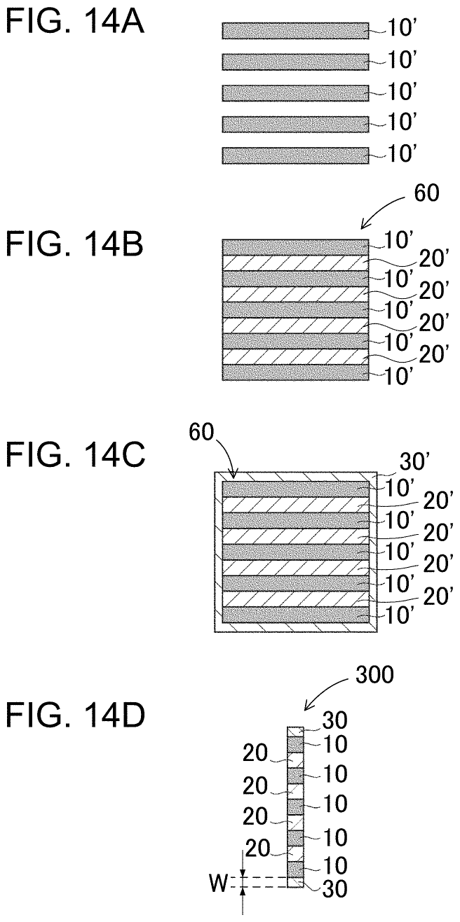

Note that for the subsequently described configuration shown in FIG. 14C the frame 30 is established around the entire perimeter of the main sheet body 100′. However, the frame can also be established around only part of the main sheet body 100′ perimeter. For example, the frame 30 can be established along the sides of the main sheet body 100′ parallel to the y-axis, but only along one part of the sides of the main sheet body 100′ parallel to the x-axis. Even in this case, the properties described above are amply demonstrated. In addition, this can restrain the amount of frame 30 material used, and is advantageous from the standpoint of material and cost reduction.

### (Heat Conducting Sheet Application Modes)

The following describes modes of application for the heat conducting sheet embodiments. The heat conducting sheet of the embodiments has exceptional thermal conductivity particularly in the thickness direction and has superior flexibility as well. Accordingly, the heat conducting sheet can be used constructively in cooling (dissipating heat from) high temperature heat-generating components HG. The heat conducting sheet of the embodiments is typically applied in contact with at least part of the surface of a high temperature component. Depending on properties such as size and shape of the high temperature component, the heat conducting sheet can be cut to meet requirements. Further, a plurality of heat conducting sheets can also be applied to a single high temperature component.

The high temperature component is not particularly specified, and it is sufficient for the high temperature component to be a unit with an operating temperature higher than the ambient temperature. For example, electronic components such a computer central processing unit (CPU), graphics processing unit (GPU), field-programmable gate-array (FPGA), and application specific integrated circuit (ASIC); and optical electronic components such as a light emitting diode (LED), liquid crystal system, and electro-luminescent (EL) device are candidates.

The maximum temperature attained (temperature reached without application of the heat conducting sheet) at the surface of the high temperature component is preferably greater than or equal to 40° C. and less than or equal to 250° C., more preferably greater than or equal to 50° C. and less than or equal to 200° C., and still more preferably greater than or equal to 60° C. and less than or equal to 180° C. This type of high temperature component can be, for example, an electronic component such a computer central processing unit (CPU), and graphics processing unit (GPU); an optical electronic component such as a light emitting diode (LED), liquid crystal system, and electro-luminescent (EL) device; as well a variety of batteries such as a lithium ion battery.

### Method of Manufacture of Heat Conducting Sheet for the First Embodiment

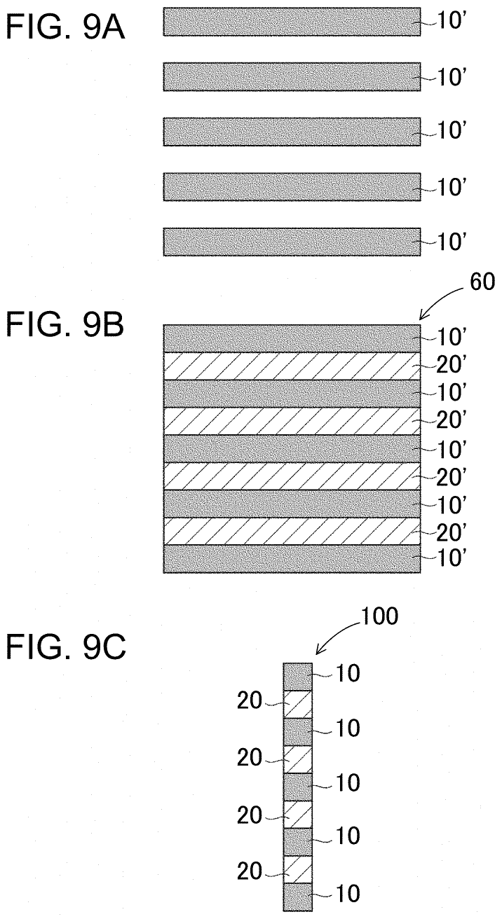

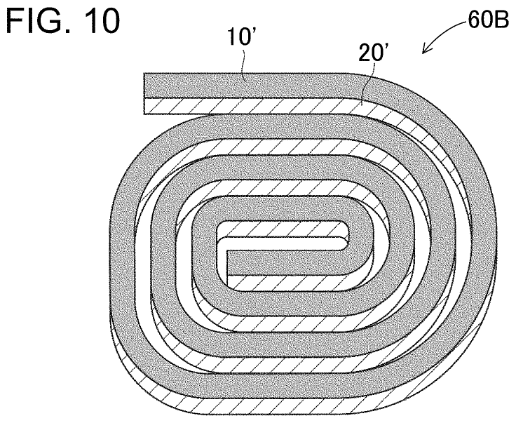

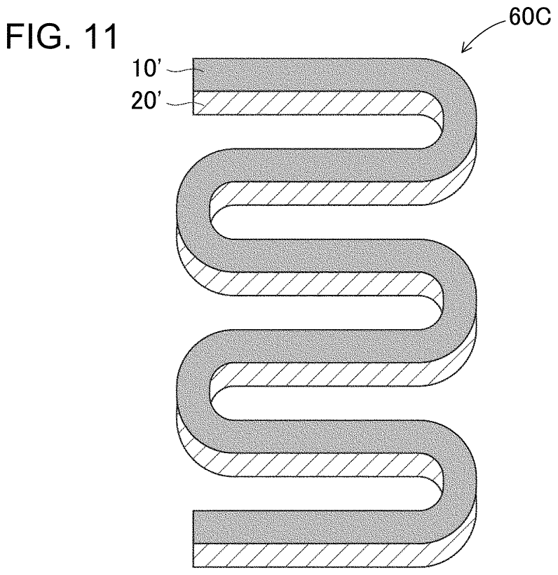

The following describes the method of manufacture of heat conducting sheet for the embodiments. First, the method of manufacture of heat conducting sheet 100 for the previously detailed first embodiment is described with reference to FIGS. 9A-11. Here, FIGS. 9A-9C are schematic cross-sections illustrating a method of manufacture of heat conducting sheet for the first embodiment, and FIGS. 10 and 11 are schematic cross-sections illustrating different examples of the layering (stacking) process to manufacture heat conducting sheet for the first embodiment.

The method of manufacture of heat conducting sheet for the first embodiment includes:
a heat conducting region pre-form sheet preparation step as shown in FIG. 9A that prepares pre-form sheet 10′ to form the heat conducting regions 10;
a layering (stacking) step as shown in FIG. 9B that layers the heat conducting region pre-form sheet 10′ with intervening resin material 20′ to produce a layered stack 60; and
a cutting step as shown in FIG. 9C that cuts the layered stack 60 in the heat conducting region pre-form sheet 10′ stacking direction.
   This makes it possible to provide a heat conducting sheet method of manufacture that can aptly produce heat conducting sheet with exceptional flexibility as well as thermal conductivity in the thickness direction. Details of each process step are described below.

### (Heat Conducting Region Pre-Form Sheet Preparation Step)

As shown in FIG. 9A, the heat conducting region pre-form sheet preparation step prepares heat conducting region pre-form sheet 10′ used to form the heat conducting regions 10. For the heat conducting region pre-form sheet 10′, for example, a blend of flake (platelet) graphite 11 and resin fiber 12 (blended by a process similar to pulp mixing in paper making) can be used. Heat conducting region pre-form sheet 10′ obtained by this type of (paper making) blending results in sheet having the thickness direction of the graphite flakes (platelets) 11 favorably oriented in the thickness direction of the heat conducting region pre-form sheet 10′.

It is desirable to implement drying treatment after sheet formation by (paper making) blending. This can eliminate moisture used during blending and makes sheet handling easier. Drying also improves heat conducting region pre-form sheet 10′ structural integrity and strength.

After blending the graphite and resin fiber into sheet form, it is desirable to implement heat and pressure treatment applied in the thickness direction of the sheet. This can align graphite flakes (platelets) 11 in a more favorable orientation. Heat and pressure treatment also improves heat conducting region pre-form sheet 10′ structural integrity and strength, in addition to driving off moisture used during blending to make handling easier.

In particular, heat conducting region pre-form sheet 10′ is preferably manufactured by a method that includes the processing described below. Specifically, it is preferable to manufacture the heat conducting region pre-form sheet 10′ by a method having a (paper making) blending step that mixes flake (platelet) graphite 11 and resin fiber 12 in a manner similar to paper making; a first press processing step that applies pressure in the thickness direction to the blended sheet; a drying step; and a second press processing step that heats the blended sheet while applying pressure in the thickness direction.

The first press processing step can be suitably implemented at room temperature (e.g. greater than or equal to 10° C. and less than or equal to 35° C.). Pressure applied in the first press processing step can be, for example, greater than or equal to 1 MPa and less than or equal to 30 MPa.

The drying step can be implemented by low pressure, high temperature, or natural drying processes. In the case of high temperature drying, temperature can be greater than or equal to 40° C. and less than or equal to 100° C.

In the second press processing step, the applied temperature (temperature at the surface of the press) can be, for example, greater than or equal to 100° C. and less than or equal to 400° C. Pressure applied in the second press processing step can be, for example, greater than or equal to 1 MPa and less than or equal to 30 MPa.

The constituent materials (flake graphite 11 and resin fiber 12) are preferably materials with properties that meet the same requirements as the heat conducting region 10 materials described previously, and materials similar to the frame 30 constituents described previously can also be mentioned. This can achieve effective results equivalent to those described previously.

Thickness of the heat conducting region pre-form sheet 10′ is typically the same as the thickness of the heat conducting regions 10. In the heat conducting region pre-form sheet preparation step, normally a plurality of heat conducting region pre-form sheets 10′ are prepared, but a single long strip (similar to a bolt of cloth) can also be prepared. In this case as well, a layered configuration can be amply obtained in the layering (stacking) step described below.

### (Layering [Stacking] Step)

As shown in FIG. 9B, the layering (stacking) step layers (stacks) the heat conducting region pre-form sheet 10′ with intervening resin material 20′ to obtain a layered stack 60. The resin material 20′ is material (with the same composition as the connecting regions 20) that becomes the connecting regions 20 of the heat conducting sheet 100. Resin material 20′ used in this step can be in liquid form or in sheet form (e.g. pre-impregnated [pre-preg] sheet).

The resin material 20′ is material corresponding to the previously described resin material that makes up the connecting regions 20. More specifically, the resin material 20′ can be material with properties that meet the same requirements as the constituents of the previously described connecting regions 20, or the precursors of those materials. Precursors can be resin material such as monomers that have a low level of polymerization, dimers, oligomers, pre-polymers, and resin material with a low level of cross-linking.

The resin material 20′ can also include components not described previously such as polymerization initiator, cross-linking agent, and solvent. When the resin material 20′ is in liquid form, it is typically applied to the surfaces of the heat conducting region pre-form sheet 10′ by a coating process in this step. The amount of resin material 20′ coated onto heat conducting region pre-form sheet 10′ surfaces can be uniform or can vary with location. Further, resin material 20′ can be applied to all surfaces of the heat conducting region pre-form sheet 10′ or to only a portion of those surfaces.

In the configuration shown in FIGS. 9A and 9B, a plurality of pre-cut leaves of heat conducting region pre-form sheet 10′ are stacked with intervening resin material 20′. However, as shown in FIG. 10 for example, the layered stack 60B of heat conducting region pre-form sheet 10′ (particularly heat conducting region pre-form sheet 10′ in long strip form) coated with resin material 20′ can be wound in a roll. Or, as illustrated by the layered stack 60C in FIG. 11, the resin material 20′ coated heat conducting region pre-form sheet 10′ (particularly pre-form sheet in long strip form) can be accordion folded to form the layered stack 60C.

In the layering step, while processing to stack the heat conducting region pre-form sheet 10′ with intervening resin material 20′ is performed as a minimum, other processing can also be performed depending on requirements. For example, when the resin material 20′ contains solvent, drying can be performed by treatments such as pressure reduction, heat application, and air drying; polymerization or cross-linking treatment can be implemented to increase polymerization or cross-linking in the resin material 20′; and press processing can be implemented to increase adhesion between the heat conducting region pre-form sheet 10′ and the resin material 20′ (between heat conducting regions 10 and connecting regions 20).

Further, the targeted configuration of layered stack 60 can also be obtained by first preparing a plurality of heat conducting region pre-form sheets 10′ joined via resin material 20′ as a stack unit, and subsequently layering multiple stack units to form the desired layered stack 60.

### (Cutting Step)

As shown in FIG. 9C, the cutting step cuts the layered stack 60 in the stacking direction of the heat conducting region pre-form sheets 10′ (thickness direction of the layered stack 60). This results in the previously described heat conducting sheet 100. In particular, by making a plurality of cuts, a plurality of heat conducting sheets 100 can be produced. By adjusting the pitch between multiple cuts, heat conducting sheet 100 of the desired thickness can be produced. When a plurality of heat conducting sheets 100 are produced, heat conducting sheet 100 thickness can be uniform or thickness can be different for different sheets. In addition, the layered stack 60 can be cut in a manner that produces heat conducting sheet 100 with thickness that varies according to location on the sheet.

The cutting step can also be performed with the layered stack 60 in a cooled (refrigerated) condition. For example, cooling can effectively restrain resin material 20′ elastic deformation allowing efficient cutting operation. Even when the width between cuts (heat conducting sheet 100 thickness T100) is relatively thin, cooling allows the cutting step to be suitably implemented while effectively preventing yield loss. When cutting is performed with the layered stack 60 in a cooled state, temperature of the layered stack 60 preferably less than or equal to 10° C., more preferably less than or equal to 0° C., and still more preferably less than or equal to −10° C. This results in more marked display of the previously described properties.

### Method of Manufacture of Heat Conducting Sheet for the Second Embodiment

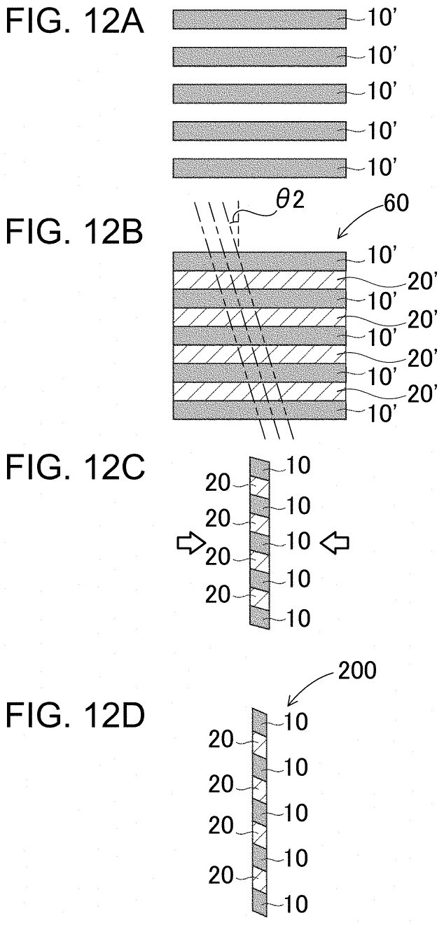

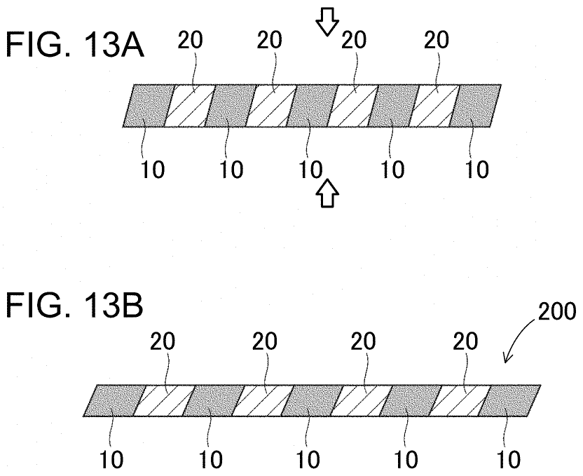

The following describes the method of manufacture of heat conducting sheet for the second embodiment based on FIGS. 12A-13B. FIGS. 12A-12D are schematic cross-sections illustrating a method of manufacturing heat conducting sheet for the second embodiment. FIGS. 13A and 13B are vertical cross-sections schematically illustrating the change in heat conducting sheet thickness and heat conducting region inclination due to press processing. FIG. 13A shows conditions prior to press processing, and FIG. 13B shows the heat conducting sheet configuration after pressing. The following description focuses on differences between the previously described embodiment, and description of like items is appropriately abbreviated.

The method of manufacture of heat conducting sheet for the second embodiment includes:
a heat conducting region pre-form sheet preparation step as shown in FIG. 12A that prepares pre-form sheet 10′ to form the heat conducting regions 10;
a layering (stacking) step as shown in FIG. 12B that layers the heat conducting region pre-form sheet 10′ with intervening resin material 20′ to produce a layered stack 60;
a cutting step as shown in FIG. 12B that cuts the layered stack 60 in a direction having a given degree of inclination from the heat conducting region pre-form sheet 10′ stacking direction; and
a pressing step as shown in FIG. 12C that applies surface pressure in the thickness direction of the heat conducting sheet 200 obtained by cutting.
   In the cutting step shown in FIGS. 12B and 12C, the layered stack 60 is cut in a direction that is inclined by a given angle θ2 from the stacking direction of the heat conducting region pre-form sheet 10′ (from the thickness direction of the layered stack 60). Namely, except for difference in the layered stack 60 cutting direction and addition of a pressing step, this method of manufacture is the same as that for the first embodiment. Accordingly, heat conducting sheet 200, as shown in FIG. 6, which has a normal (vector) N100 to the heat conducting sheet 200 that is not perpendicular to the normal (vectors) to the heat conducting regions 10, can be manufactured in straightforward manner.

By implementing a pressing step as shown in FIG. 12C after the cutting step, adhesion between heat conducting regions 10 and connecting regions 20 is increased compared to the configuration prior to pressing, and heat conducting sheet having exceptional durability can be produced. This enables thinner heat conducting sheet 200 to be readily manufactured. The pressing step also allows the angle between normal (vector) N100 to the heat conducting sheet 200 and the normal (vectors) to the heat conducting regions 10 to be fine tuned (refer to FIGS. 13A and 13B).

The layered stack 60 cutting direction in the cutting step preferably satisfies the following conditions. Specifically, the angle θ₂ between the cutting direction and the heat conducting region pre-form sheet 10′ stacking direction (i.e. direction normal to the heat conducting region pre-form sheet 10′, which is the thickness direction of the layered stack 60) is preferably greater than or equal to 5° and less than or equal to 85°, more preferably greater than or equal to 7° and less than or equal to 60°, still more preferably exceeding 10° and less than or equal to 50°, and most preferably exceeding 15° and less than or equal to 40°. This results in more discernible display of the previously described properties.

While pressure applied in the pressing step is not specifically limited, it is preferably greater than or equal to 0.01 MPa and less than or equal to 1 MPa, more preferably greater than or equal to 0.03 MPa and less than or equal to 0.7 MPa, and still more preferably greater than or equal to 0.05 MPa and less than or equal to 0.5 MPa. This results in more marked display of the previously described properties.

### Method of Manufacture of Heat Conducting Sheet for the Third Embodiment

Next, the method of manufacturing heat conducting sheet for the third embodiment is described based on FIGS. 14A-14D. FIGS. 14A-14D are schematic cross-sections illustrating a method of manufacturing heat conducting sheet 300 for the third embodiment. Again, the following description focuses on differences between the previously described embodiments, and description of like items is appropriately abbreviated.

The method of manufacture of heat conducting sheet 300 for the third embodiment includes:
a heat conducting region pre-form sheet preparation step as shown in FIG. 14A that prepares pre-form sheet 10′ to form the heat conducting regions 10;
a layering (stacking) step as shown in FIG. 14B that layers the heat conducting region pre-form sheet 10′ with intervening resin material 20′ to produce a layered stack 60;
a frame formation layering step as shown in FIG. 14C that establishes a frame formation layer 30′ on the layered stack 60; and
a cutting step as shown in FIG. 14D that cuts the layered stack 60 and frame formation layer 30′ in the heat conducting region pre-form sheet 10′ stacking direction.
   Namely, except for inclusion of a frame formation layering step between the layering step and the cutting step, this method of manufacture is the same as the previously described method of manufacture for the first embodiment.

Heat conducting sheet 300 produced by this method of manufacture exhibits, for example, properties previously described for a frame 30 established around the perimeter of a main sheet body. Further, unintentional layered stack 60 deformation during the cutting step can be constrained, for example, and unintentional variation in the thickness of the cut heat conducting sheet 300 can be effectively prevented.

Note that FIG. 14D illustrates cutting step results when the layered stack 60 is cut in the heat conducting region pre-form sheet 10′ stacking direction (thickness direction of the layered stack 60). However, as described previously for the second embodiment, the layered stack 60 can also be cut at a given angle with respect to heat conducting region pre-form sheet 10′ stacking direction (thickness direction of the layered stack 60). In addition, the method of manufacture of heat conducting sheet 300 for the third embodiment can also include a pressing step after the cutting step as described in the method of manufacture for the second embodiment.

### (Frame Formation Layering Step)

In the frame formation layering step illustrated in FIG. 14C, frame formation layer 30′ is established on the layered stack 60. While the frame formation layer 30′ can be established on the layered stack 60 in any configuration, it is preferably seated on at least part of the two side-walls and contiguous upper and lower surfaces of the layered stack 60. This configuration allows previously described frame 30 functions to be effectively exhibited, for example, in the heat conducting sheet 300. Further, unintentional layered stack 60 deformation during the subsequent cutting step can be effectively controlled, for example, and unintentional variation in the thickness of the cut heat conducting sheet 300 can be effectively prevented.

In the configuration shown in the figures, frame formation layer 30′ is established in a continuous manner on opposing side-walls as well as upper and lower surfaces of the layered stack 60. This enables the previously mentioned effective results to be distinctly exhibited.

For the heat conducting sheet 300 of the third embodiment, the frame formation layering step can also be implemented by winding the frame formation layer 30′ around the layered stack 60. Winding attachment during the frame formation layering step allows more effective prevention of unintentional delamination or detachment of the frame formation layer 30′, and more certainly realizes the previously described effects. It also produces a layered stack 60 with exceptional structural integrity for the cutting step.

When frame formation layer 30′ is established on the layered stack 60 by winding, frame formation layer 30′ thickness is preferably greater than or equal to 3 μm and less than or equal to 100 μm, more preferably greater than or equal to 5 μm and less than or equal to 80 μm, and still more preferably greater than or equal to 7 μm and less than or equal to 50 μm. This produces heat conducting sheet 300 with sufficiently superior flexibility, and markedly exhibits the previously described effects.

Constituent materials of the frame formation layer 30′ can be the same as those detailed previously for the frame 30, and preferably are materials meeting requirements specified for the previously described frame 30. This allows previously described properties to be realized.

### Method of Manufacture of Heat Conducting Sheet for the Fourth Embodiment

In the above examples, a method of layering heat conducting region pre-form sheet 10′ with intervening resin material 20′ was described. However, the present invention does not limit the method of producing a layered structure of heat conducting regions and connecting regions to that cited above. For example, heat conducting region pre-form sheet 10′ can be layered after impregnation with resin material 20′ and by curing (hardening) the resin material 20′ within the layered heat conducting region pre-form sheet 10′, a heat conducting region and connecting region laminate structure can be obtained. Further, besides layering multiple heat conducting region pre-form sheets 10′ each precut in individual sheet form, the layering method can wind-up or fold heat conducting region pre-form sheet prepared as a single piece to produce the layered structure.

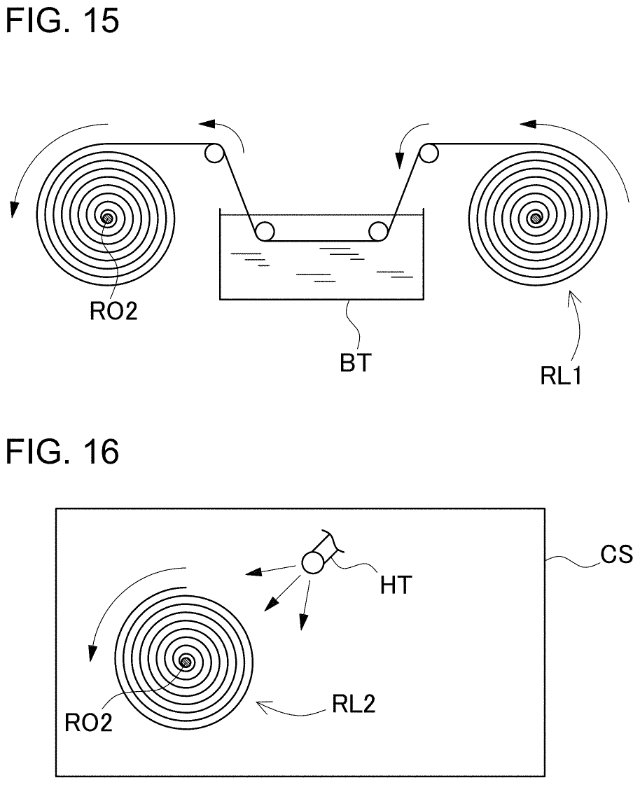

For example, as shown in FIG. 15 a pre-wound (cylindrical) roll RL1 of heat conducting region pre-form sheet 10′ can be prepared. One end of the heat conducting region pre-form sheet 10′ can be drawn out from the (cylindrical) roll RL1 and impregnated with resin material 20′ in liquid form. For example, heat conducting region pre-form sheet 10′ drawn out from the roll can be immersed in a bath of liquid resin material 20′ BT, or resin material 20′ can be applied by coating methods such as feeding the heat conducting region pre-form sheet 10′ through rollers with one roller partially immersed in resin material 20′, by die-coat methods, or by spray application.

Heat conducting region pre-form sheet 10′, which is impregnated or coated with resin material 20′ in this manner, is subsequently wound onto another roller RO2. In this form, the resin material 20′ is cured (hardened) to obtain a layered stack 60D. For example, by using thermoplastic or ultraviolet (UV) curable resin and hardening the uncured resin material 20′ impregnated in the layered heat conducting region pre-form sheet 10′ by processing such as heat or UV application, a resin-cured layered stack 60D can be produced as a (cylindrical) roll RL2. As shown in FIG. 16 for example, resin material 20′ curing can be performed in an enclosure CS where the (cylindrical) roll RL2 is heated by a heater HT or irradiated with UV light while being rotated.

This method also allows adjustment of the amount of unhardened resin material 20′ impregnating the layered heat conducting region pre-form sheet 10′. The amount of impregnated resin material 20′ can be calculated by weighing the original (cylindrical) roll RL1 and subtracting that weight from the weight of the resin material 20′ impregnated (cylindrical) roll RL2. If the amount of resin material 20′ impregnated in the heat conducting region pre-form sheet 10′ is too large, the (cylindrical) roll RL2 can be rotated to remove excess resin material 20′ by centrifugal force and adjust the impregnated resin material 20′ to the desired amount. If too little resin material 20′ is impregnated in the heat conducting region pre-form sheet 10′, the impregnating process can be repeated to again impregnate the heat conducting region pre-form sheet 10′ with resin material 20′. Further, if resin material 20′ is left in the uncured state in the (cylindrical) roll RL2, some of that resin material 20′ will drip-off naturally to adjust the impregnated quantity. However, in this case as well, it is desirable to rotate the (cylindrical) roll RL2 at a given rotation rate to insure uniform distribution of resin material 20′ within the (cylindrical) roll.

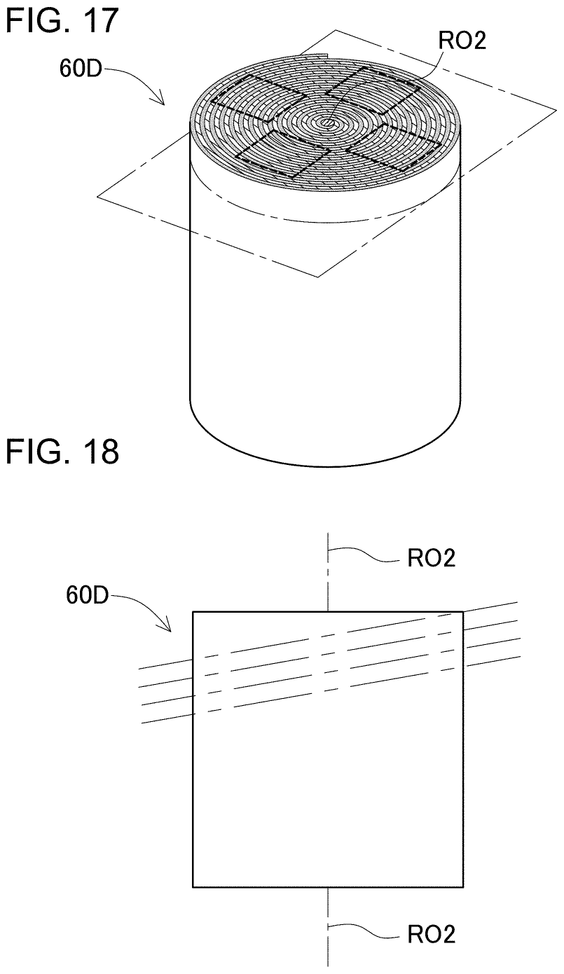

With the desired quantity of resin material 20′ impregnated in the (cylindrical) roll RL2, the resin material 20′ is cured (hardened) to produce the (cylindrical) roll layered stack 60D. Further, the cutting process is implemented with respect to that layered stack 60D. As shown in the oblique cross-section of FIG. 17, planes perpendicular to the axis of the (cylindrical) roll RL2 are taken as cutting planes, and the width (pitch) between parallel cutting planes corresponds to the thickness of the cut heat conducting sheet 100. This produces heat conducting sheet in raw sheet form. Depending on requirements, heat conducting sheet in raw sheet form is cut to the desired size (e.g. broken line rectangular shapes shown in FIG. 17) to produce the required heat conducting sheet 100. Note that interfaces between heat conducting regions 10 and connecting regions 20 in heat conducting sheet 100 produced by this processing are not established as straight lines as shown in FIG. 3, but rather have a curved arc shape. There is also slight difference in arc pattern depending on cutting location within the raw heat conducting sheet.

Further, orientation of layered stack 60D cutting planes is not limited to being perpendicular to the roller RO2 (axis of the [cylindrical] roll layered stack 60D) as shown in FIG. 17, and for example, cutting can be performed along planes inclined with respect to the roller RO2 as shown in the side view of FIG. 18. This cutting method can result in raw heat conducting sheet having interfaces between heat conducting regions 10 and connecting regions 20 that are inclined as shown in the cross-section of FIG. 7.

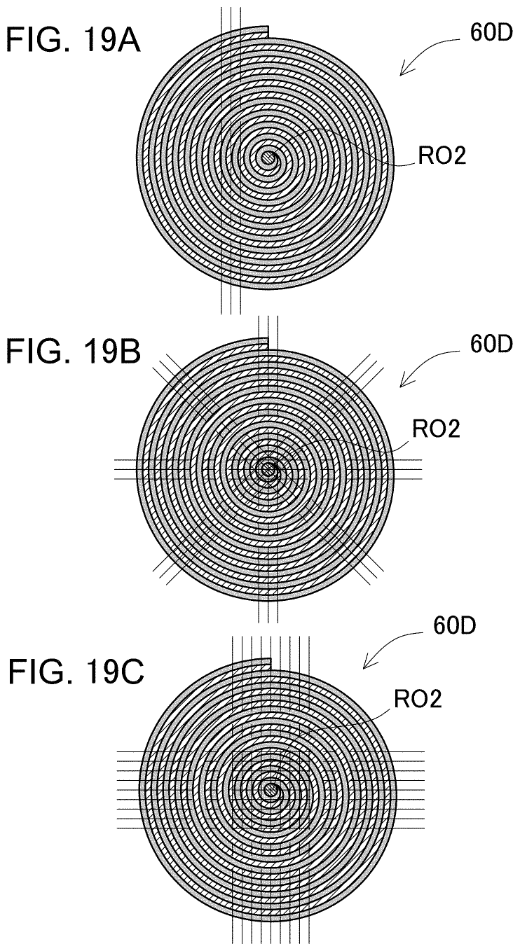

As shown in the cross-sections of FIGS. 19A-190, cutting can also be performed along planes parallel to the roller RO2 (axis) in the (cylindrical) roll RL2. In this case as well, cutting planes are parallel and the width (pitch) between parallel cutting planes corresponds to the thickness of the cut heat conducting sheet 100. This produces heat conducting sheet in raw sheet form. Again, the raw heat conducting sheet is cut to the desired size depending on requirements to produce the necessary heat conducting sheet 100. Note that the heat conducting region 10 and connecting region 20 pattern in this heat conducting sheet 100 does not have uniform width and angular orientation as shown in FIG. 3, but rather has some inclination. Further, depending on the cutting location of the raw heat conducting sheet, there is some difference in heat conducting region 10 and connecting region 20 width and angular orientation. The example shown in FIG. 19A shows a cutting location that does not pass through the roller RO2 (center of the roll). However, cutting is not limited to that example and as shown in the cross-section of FIG. 19B, cutting sections that pass through the radius of the roller RO2 are also possible. This cutting method produces raw heat conducting sheet with a heat conducting region 10 and connecting region 20 pattern that is independent of cutting position, and can produce uniform heat conducting sheets 100 from a single layered stack 60D. In addition, as shown in the cross-section of FIG. 19C, cutting can be performed along parallel planes in a given region centered around the roller RO2, and the remaining region can be cut along planes perpendicular to those cutting planes. This method does not make oblique cuts as shown in FIG. 19B, and limits cutting to only the vertical and horizontal cuts shown in FIG. 19C. This has the positive feature of simplifying the cutting operation.

Note that the configuration of rolled heat conducting region pre-form sheet 10′ is not necessarily limited to the perfectly round cross-section shown in FIG. 15, and the heat conducting region pre-form sheet 10′ can also be wound into shapes such as elliptical or oblong (super-elliptical). Further, although the above examples showed (cylindrical) roll configurations wound around a central roller RO2, the (cylindrical) rolls can also be coreless.

Further, while the examples above described rectangular (viewed from above) heat conducting sheets 100, it should be clear that heat conducting sheet 100 can be suitably shaped corresponding to heat-generating component HG and heat sink shapes.

Although preferred embodiments of the present invention are described above, the present invention is not limited to those embodiments. For instance in the heat conducting sheet method of manufacture, other processing steps (i.e. pre-processing, intermediate processing, post processing) can be added. For example, a sheet surface polishing step can be included as post processing after the cutting step. This not only externally exposes heat conducting regions more favorably from heat conducting sheet primary surfaces, it can also finely adjust sheet surface roughness Ra. Further, the pressing step in the previously described method of manufacture of heat conducting sheet for the second embodiment can be omitted.

Heat conducting sheet for the present invention is not limited to sheet manufactured by methods described above and can be sheet manufactured by any method. In addition, the heat conducting sheet of the present invention can be sheet configured with elements other than heat conducting regions, connecting regions, and frame regions.

The following describes details of implementations of the present invention and comparison examples, but the present invention is not limited to those implementations and examples. Note when temperature conditions for processing and measurements are not cited below, a temperature of 20° C. is assumed.

### (1) Heat Conducting Sheet Fabrication

Heat conducting sheet for each of the implementations and comparison examples was fabricated as follows.

### (Implementation 1)

### (Heat Conducting Region Pre-Form Sheet Fabrication)

First, aramid resin as the resin fiber and expanded graphite as the flake graphite were blended ([paper making] blending step), and subsequently the blended sheet was press processed (first press processing step) at 20° C. with a pressure of 1 MPa. After drying at 140° C., press processing at 180° C. with a pressure of 1 MPa (second press processing step) was performed for 2 min, and cutting into a plurality of 150 mm×150 mm square sheets resulted in multiple heat conducting region pre-form sheets. The thickness direction of graphite flakes (platelets) in the heat conducting region pre-form sheet was oriented in the thickness direction of the heat conducting region pre-form sheet, and the thickness of the heat conducting region pre-form sheet was 65 μm.

### (Layered Stack Fabrication)

Next, one of the heat conducting region pre-form sheets was placed on a glass plate, and 3 g of SeRM elastomer (Advanced Soft Materials [ASM] Inc.), which is a solvent-less liquid elastomer material, was coated as the resin material over the entire upper primary surface of the heat conducting region pre-form sheet. SeRM elastomer contains (toroidal) ring molecules, first polymer that has linear chain (string) molecules threaded through the ring molecules, polyrotaxane that is first polymer with blocking end groups at both ends of the first polymer, and second polymer. Here, the polyrotaxane and second polymer are linked via the ring molecules and previously described preferable conditions are satisfied.

Next, an uncoated heat conducting region pre-form sheet was placed on top of the heat conducting region pre-form sheet coated with resin material as described above. By repeated application of SeRM elastomer (Advanced Soft Materials [ASM] Inc.) to the upper layer of heat conducting region pre-form sheet and placement of another uncoated heat conducting region pre-form sheet on top of the coated sheet, a layered stack having 25 layers of heat conducting region pre-form sheet and 25 layers of resin material was obtained.

Next, the layered stack was sandwiched between two glass plates and pressed via clamps to compress and bond the layers together. In this state, heating for 3 hrs at 150° C. was performed to cure the SeRM elastomer resin material.

### (Heat Conducting Sheet Fabrication)

The layered stack produced as described above (layered stack with SeRM elastomer resin material in the cured state) was cut in the thickness direction (cutting step), and surfaces were polished via polishing (abrasive) paper (polishing step) to produce heat conducting sheet as shown in FIGS. 2-4.

Heat conducting sheet fabricated in this manner had a plurality of heat conducting regions as layers and connecting regions joined to those heat conducting regions forming an overall sheet configuration. Heat conducting region material composition included flake graphite and resin fiber, and those heat conducting regions were established extending from one primary surface to the other primary surface of the heat conducting sheet. Connecting regions were composed of resin material having flexibility. The thickness direction of the graphite flakes (platelets) was oriented in the thickness direction of the stacked heat conducting regions, and normal to the heat conducting sheet formed a 90° angle with respect to normals to the heat conducting regions.

Namely, when a coordinate system with mutually perpendicular x and y axes in the plane of a heat conducting sheet primary surface and a z-axis perpendicular to that plane is established (refer to FIG. 3), thermal conductivity was higher in the z-direction than in the y-direction. Further, the heat conducting sheet was provided with a plurality of heat conducting regions extending in the x-direction and connecting regions composed of flexible resin material that connected with each heat conducting region in the y-direction. Heat conducting regions were composed of material including resin fiber and flake graphite oriented with the thickness direction of the flakes (platelets) in line with the y-axis.

Thickness of the heat conducting sheet fabricated in this manner was 0.3 mm, and surface roughness Ra of both surfaces of the heat conducting sheet was 50 μm. Thickness of the heat conducting regions formed from heat conducting region pre-form sheet was 65 μm, and thickness of the connecting regions composed of cured SeRM elastomer resin material was 50 μm. Further, the percentage of resin fiber content within the heat conducting regions was 25% by mass, and the percentage of flake graphite content was 75% by mass.

### (Implementations 2-5)

Heat conducting sheet was fabricated in the same manner as implementation 1 except for configuration differences shown in Table 1. Those configuration differences were changes in resin fiber and flake graphite properties, type of resin material used in the connecting regions, coating conditions, and stacking conditions of the heat conducting region pre-form sheet and resin material.

### (Implementation 6)

Heat conducting sheet was fabricated in the same manner as implementation 1 except that cutting direction (refer to FIGS. 2, 6, and 7) was inclined 19° with respect to the heat conducting region pre-form sheet stacking direction (direction of the normal to the heat conducting region pre-form sheets), and a press processing, which applied pressure in the thickness direction of the cut sheet, was added between the cutting step and polishing step. Pressure in the press processing was 0.2 MPa.

### (Implementations 7-10)

Heat conducting sheet was fabricated in the same manner as implementation 6 except for configuration differences shown in Table 1. Those configuration differences were changes in resin fiber and flake graphite properties, type of resin material used in the connecting regions, coating conditions, stacking conditions of the heat conducting region pre-form sheet and resin material, and the angle of the cutting direction with respect to the heat conducting region pre-form sheet stacking direction (direction of the normal to the heat conducting region pre-form sheets) during the cutting step.

### (Implementation 11)

First, a layered stack (with cured SeRM elastomer as resin material) having 25 layers of heat conducting region pre-form sheet and 25 layers of resin material was obtained by the same processing as that for implementation 1.

Next, 11 μm thick polyvinylidene chloride film was wound around the top and bottom surfaces and two opposing side-walls of the layered stack entirely covering those surfaces and establishing a frame formation layer with an average width of 100 μm.

Subsequently, the layered stack with frame formation layer established as described above was cut in the thickness direction (cutting step), and surfaces were polished via polishing (abrasive) paper (polishing step) to produce heat conducting sheet having a main sheet body provided with heat conducting regions and connecting regions and a frame in contact with the perimeter of that main sheet body (refer to FIG. 8).

### (Implementations 12-15)

Heat conducting sheet was fabricated in the same manner as implementation 6 except for configuration differences shown in Table 2. Those configuration differences were changes in resin fiber and flake graphite properties, type of resin material used in the connecting regions, coating conditions, stacking conditions of the heat conducting region pre-form sheet and resin material, and frame formation layer properties.

### (Implementation 16)

First, a layered stack (with cured SeRM elastomer as resin material) having 25 layers of heat conducting region pre-form sheet and 25 layers of resin material was obtained by the same processing as that for implementation 1.

Next, 11 μm thick polyvinylidene chloride film was wound around the top and bottom surfaces and two opposing side-walls of the layered stack entirely covering those surfaces and establishing a frame formation layer with an average width of 100 μm.

Subsequently, the layered stack with frame formation layer established as described above was cut (cutting step), pressure was applied to the cut sheet in the thickness direction (pressing step), and surfaces were polished via polishing (abrasive) paper (polishing step) to produce heat conducting sheet having a main sheet body provided with heat conducting regions and connecting regions and a frame in contact with the perimeter of that main sheet body (refer to FIG. 8). The cutting direction in the cutting step was adjusted to make a 19° angle with respect to the heat conducting region pre-form sheet stacking direction (direction of the normal to the heat conducting region pre-form sheets).

### COMPARISON EXAMPLE 1

Here, the heat conducting region pre-form sheet fabricated as in implementation 1 was used as-is for the heat conducting sheet. Namely, graphite flakes (platelets) were oriented with their thickness direction aligned with the thickness direction of the heat conducting sheet.

### Comparison Example 2

Heat conducting sheet was fabricated in the same manner as implementation 6 except during heat conducting region pre-form sheet formation spherical graphite (graphite particulate) was used in place of flake graphite. Average particulate size of the graphite was 20 μm.

The configuration of each of the implementations and comparison examples is summarized in Tables 1 and 2. Each heat conducting sheet had all heat conducting regions and connecting regions exposed from both primary surfaces. In Tables 1 and 2, cured SeRM elastomer (Advanced Soft Materials [ASM] Inc.) was indicated as [SeRM], and cured flexible phenol resin (DIC Corp. J-325) was indicated as [PH]. Further, in Tables 1 and 2, the angle between the normal to the heat conducting sheet and the normal to the heat conducting regions was indicated as [θ₁], and the angle between the layered stack cutting direction and the heat conducting region pre-form sheet stacking direction was indicated as [θ₂]. The flake graphite used in all the implementations had average flatness greater than or equal to 3 and less than or equal to 100, and average flake (platelet) thickness greater than or equal to 0.2 μm and less than or equal to 50 μm. Further, in all the implementations, the number of graphite flakes (platelets) in the heat conducting regions that had their thickness direction (direction normal to the platelet) aligned within 10° to the y-axis direction was 80% of the total number of flakes (platelets).

TABLE 1

| | Heat conducting region | | | | | | | | Connecting region | | | | | | |
|---|---|---|---|---|---|---|---|---|---|---|---|---|---|---|---|
| | Constituent material | | | | | | | vol- | | | vol- | | sur- | | |
| Imple- | Graphite | | Resin fiber | | | | thick- | ume- | | thick- | ume- | thick- | face | | |
| menta- | | % by | | length | width | % by | ness | tric | | ness | tric | ness | Ra | θ₁ | θ₂ |
| tion | Form | mass | type | [mm] | [μm] | mass | [μm] | % | type | [μm] | % | [mm] | [μm] | [°] | [°] |
| 1 | Flake | 75 | aramid | 2 | 20 | 25 | 65 | 57 | SeRM | 50 | 43 | 3 | 50 | 90 | 0 |
| 2 | Flake | 50 | aramid | 2 | 20 | 25 | 65 | 57 | SeRM | 50 | 43 | 3 | 50 | 90 | 0 |
| 3 | Flake | 85 | aramid | 2 | 20 | 15 | 65 | 57 | SeRM | 50 | 43 | 3 | 50 | 90 | 0 |
| 4 | Flake | 75 | aramid | 2 | 20 | 25 | 100 | 67 | SeRM | 50 | 33 | 3 | 50 | 90 | 0 |
| 5 | Flake | 75 | aramid | 2 | 20 | 25 | 65 | 57 | PH | 50 | 43 | 3 | 50 | 90 | 0 |
| 6 | Flake | 75 | aramid | 2 | 20 | 25 | 65 | 57 | SeRM | 50 | 43 | 2.5 | 50 | 71 | 19 |
| 7 | Flake | 75 | aramid | 2 | 20 | 25 | 65 | 57 | SeRM | 50 | 43 | 3 | 50 | 71 | 19 |
| 8 | Flake | 75 | aramid | 2 | 20 | 25 | 65 | 57 | SeRM | 50 | 43 | 3 | 50 | 80 | 10 |
| 9 | Flake | 75 | aramid | 2 | 20 | 25 | 65 | 57 | SeRM | 50 | 43 | 3 | 50 | 50 | 40 |
| 10 | Flake | 75 | aramid | 2 | 20 | 25 | 65 | 57 | PH | 50 | 43 | 3 | 50 | 45 | 45 |

TABLE 2

| | Heat conducting region | | | | | | | | Connecting region | | | Frame | | |
|---|---|---|---|---|---|---|---|---|---|---|---|---|---|---|
| | Constituent material | | | | | | | vol- | | | vol- | | | vol- |
| Imple- | Graphite | | Resin fiber | | | | thick- | ume- | | thick- | ume- | | | ume- |
| menta- | | % by | | length | width | % by | ness | tric | | ness | tric | | width | tric |
| tion | form | mass | type | [mm] | [μm] | mass | [μm] | % | type | [μm] | % | type | [μm] | % |
| 11 | Flake | 75 | aramid | 2 | 20 | 25 | 65 | 55 | SeRM | 50 | 41 | PVDC | 100 | 4 |
| 12 | Flake | 50 | aramid | 2 | 20 | 25 | 65 | 55 | SeRM | 50 | 41 | PVDC | 100 | 4 |
| 13 | Flake | 85 | aramid | 2 | 20 | 15 | 65 | 55 | SeRM | 50 | 41 | PVDC | 100 | 4 |
| 14 | Flake | 75 | aramid | 2 | 20 | 25 | 100 | 65 | SeRM | 50 | 31 | PVDC | 100 | 4 |
| 15 | Flake | 75 | aramid | 2 | 20 | 25 | 65 | 55 | PH | 50 | 41 | PVDC | 100 | 4 |
| 16 | Flake | 75 | aramid | 2 | 20 | 25 | 65 | 55 | SeRM | 50 | 41 | PVDC | 100 | 4 |
| CE 1 | Flake | 75 | aramid | 2 | 20 | 25 | — | 100 | — | — | — | — | — | — |
| CE 2 | Sphere | 75 | aramid | 2 | 20 | 25 | 65 | 57 | SeRM | 50 | 43 | — | — | — |

| | | sur- | | |
|---|---|---|---|---|
| Imple- | thick- | face | | |
| menta- | ness | Ra | θ₁ | θ₂ |
| tion | [mm] | [μm] | [°] | [°] |
| 11 | 3 | 50 | 90 | 0 |
| 12 | 3 | 50 | 90 | 0 |
| 13 | 3 | 50 | 90 | 0 |
| 14 | 3 | 50 | 90 | 0 |
| 15 | 3 | 50 | 90 | 0 |
| 16 | 2.5 | 60 | 71 | 19 |
| CE 1 | 65 μm | 90 | 0 | 90 |
| CE 2 | 2.5 | 60 | 71 | 19 |

*CE = comparison example

### (2) Evaluation (Assessment)

First, thermal conductivity of the heat conducting sheet for each implementation and comparison example was measured by the laser-flash method and reported in Table 3. Laser-flash method thermal conductivity was measured using a Netzsch LFA447 NanoFlash thermal conductivity measurement system.

TABLE 3

| | Thermal conductivity |
|---|---|
| Implementation | W/m · K |
| 1 | 41 |
| 2 | 30 |
| 3 | 42 |
| 4 | 38 |
| 5 | 31 |
| 6 | 46 |
| 7 | 38 |
| 8 | 39 |
| 9 | 32 |
| 10 | 30 |
| 11 | 44 |
| 12 | 35 |
| 13 | 44 |
| 14 | 41 |
| 15 | 38 |
| 16 | 46 |
| CE 1 | 1.3 |
| CE 2 | 4 |

*CE = comparison example

The CPU on the mother-board of an off-the-shelf personal computer (Fujitsu FMVD13002) was used to evaluate the heat conducting sheets. The cooling fin heat sink attached via grease (heat sink compound) to the CPU was removed, and the grease was meticulously cleaned off. Next, heat conducting sheet for implementation 1 was cut to size and seated on the CPU, and the cooling fin heat sink was re-attached. Subsequently, the computer was operated in a room with 20° C. ambient temperature and, while performing specified processing, the CPU temperature was measured via Speccy (Piriform Ltd.).

CPU temperature was measured in the same manner for implementations 2-16 and each comparison example. During measurement, CPU temperature was measured 30 min after initiation of the specified processing, and each implementation was assessed and graded A-E as described below. It is clear that the lower the CPU temperature, the higher the thermal conductivity in the heat conducting sheet thickness direction.

A: CPU temperature below 60° C.

B: CPU temperature greater than or equal to 60° C. and below 65° C.

C: CPU temperature greater than or equal to 65° C. and below 70° C.

D: CPU temperature greater than or equal to 70° C. and below 75° C.

E: CPU temperature greater than or equal to 75° C.

Assessment of each heat conducting sheet for implementations 1-16 and comparison examples 1-2 is indicated in Table 4 below.

TABLE 4

| Implementation | Assesment grade |
|---|---|
| 1 | A |
| 2 | B |
| 3 | A |
| 4 | A |
| 5 | B |
| 6 | A |
| 7 | A |
| 8 | B |
| 9 | B |
| 10 | B |
| 11 | A |
| 12 | B |
| 13 | A |
| 14 | A |
| 15 | A |
| 16 | A |
| CE 1 | E |
| CE 2 | D |

*CE = comparison example

It is clear from Table 3 that heat conducting sheet for all of the implementations had superior thermal conductivity in the thickness direction. Further, heat conducting sheet for all of the implementations had excellent flexibility with the ability to readily conform to the surface of the high temperature component CPU. Heat conducting sheet used in the assessment described above was removed from the computer and its external condition was inspected. Heat conducting region buckling was prevented and adhesion between heat conducting regions and connecting regions was maintained throughout the heat conducting sheet for implementations 6-10 and 16. In addition, heat conducting sheet for the implementations with these exceptional properties could be readily manufactured. Implementations 11-16 which employed frame formation layers made layered stack cutting particularly easy. In contrast, heat conducting sheet for the comparison examples showed unsatisfactory results.

Note when diamond grease was used in place of heat conducting sheet and the same assessment conducted, CPU temperature reached 83° C.

Further, heat conducting sheet was fabricated in the same manner as the implementations and comparison examples except for variation in the following properties. Specifically, heat conducting region thickness T10 was varied in a range greater than or equal to 50 μm and less than or equal to 300 μm, connecting region thickness T20 was varied in a range greater than or equal to 0.1 μm and less than or equal to 200 μm, the percentage of graphite flake content within the heat conducting regions was varied in a range greater than or equal to 10% by mass and less than or equal to 90% by mass, the percentage of resin fiber content within the heat conducting regions was varied in a range greater than or equal to 10% by mass and less than or equal to 90% by mass, average resin fiber length was varied in a range greater than or equal to 1.5 mm and less than or equal to 20 mm, average resin fiber width was varied in a range greater than or equal to 1.0 μm and less than or equal to 50 μm, the ratio (XG/XF) of graphite flake content XG [% by mass] to resin fiber content XF [% by mass] was varied in a range greater than or equal to 0.1 and less than or equal to 9.0, the volumetric percentage of heat conducting region contained in the entire heat conducting sheet was varied in a range greater than or equal to 30% by volume and less than or equal to 90% by volume, the volumetric percentage of connecting region contained in the entire heat conducting sheet was varied in a range greater than or equal to 10% by volume and less than or equal to 70% by volume, and the width W of the frame was varied in a range greater than or equal to 30 μm and less than or equal to 1000 μm. When heat conducting sheet with these variations was evaluated in the same manner as the implementations and comparison examples, results showed the same trends as those indicated above.

In addition, instead of single-sheet heat conducting region pre-form sheet, heat conducting region pre-form sheet in long strip form was used. When heat conducting sheet was manufactured in the same manner as the implementations and comparison examples except that long strip heat conducting region pre-form sheet coated with resin material was wound into a roll or accordion folded, the same evaluation cited above resulted in the same outcome.

### (Layered Stack Cross-Section Photographs)

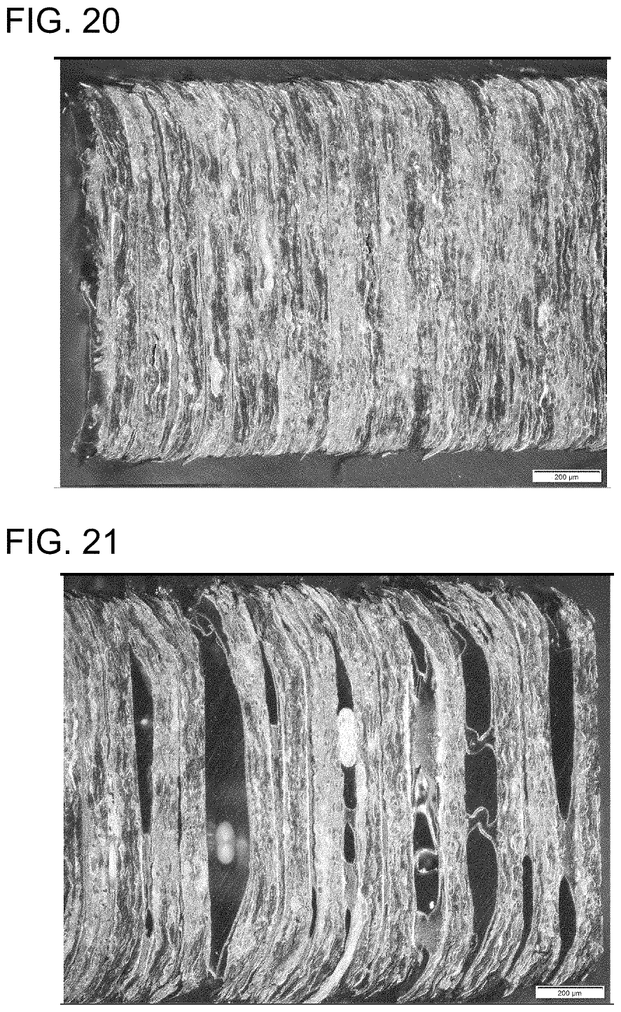

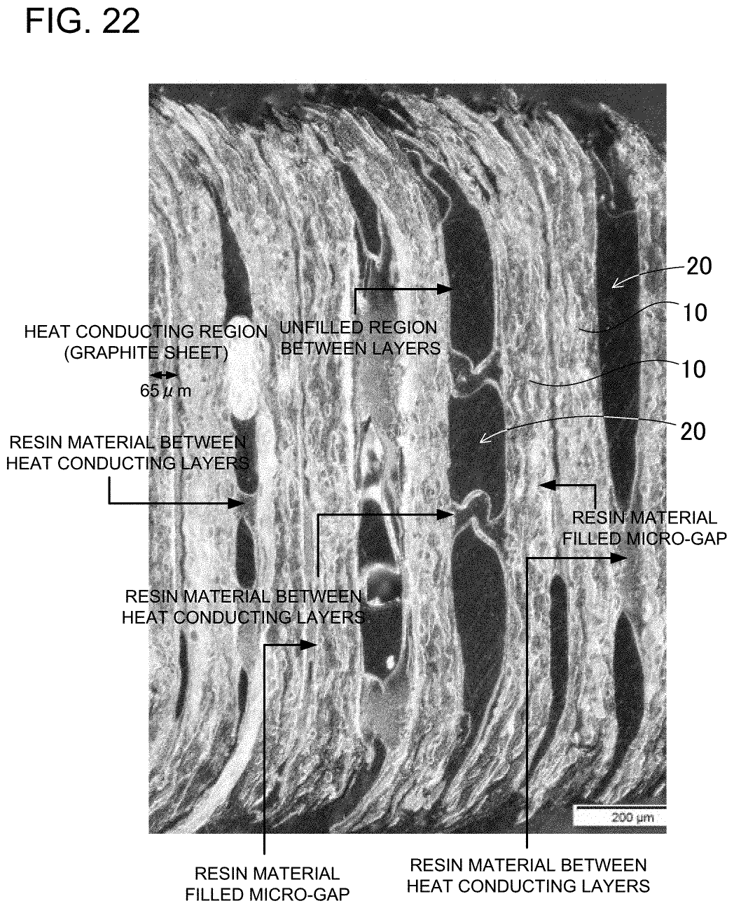

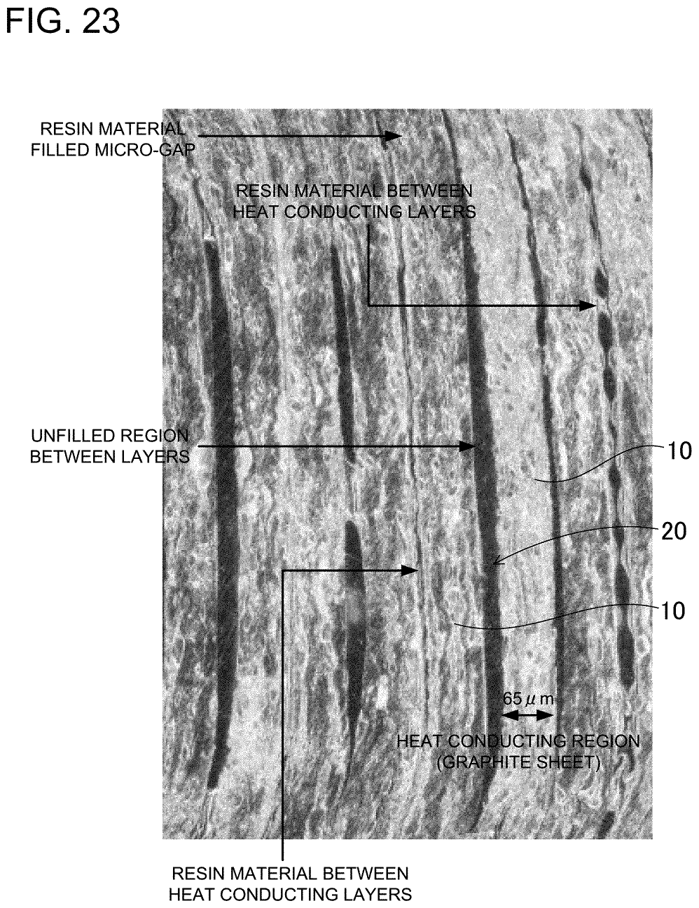

FIGS. 20-23 show enlarged cross-section photographs of heat conducting sheet for implementations described above. Here, FIG. 20 is heat conducting sheet for implementation 4, FIG. 21 is heat conducting sheet for implementation 1, FIG. 23 is an enlarged cross-section photograph of principal parts of FIG. 22, and FIG. 22 is an enlarged cross-section photograph of principal parts of the heat conducting sheet for the first embodiment. The vertical direction in each photograph corresponds to the thickness direction of the heat conducting sheet. FIG. 20 shows high density sheet and FIG. 21 shows low density sheet. As shown in FIG. 23, heat conducting region 10 thickness is approximately 65 μm in high density sheet, and connecting region 20 resin material is discernible between adjacent heat conducting region 10 layers. Here, connecting regions are not necessarily clear-cut layers, but rather have the form of partially or discretely connected resin material. Namely, regions between adjacent heat conducting regions 10 include a relatively large proportion of unfilled layers. These unfilled regions between heat conducting region layers are formed in part as layers and exist as voids between layers. Heat conducting sheet flexibility and elasticity are improved by these unfilled layers. This makes it easy for the heat conducting sheet to conform to the surface topology and roughness of heat-generating component HG and heat sink surfaces for intimate contact and good adhesion at the interfaces with those surfaces. Further, by also establishing vacancies (micro-gaps) within heat conducting regions 10, heat conducting sheet flexibility is improved. Meanwhile, by resin material ingress to fill some of the vacancies (micro-gaps) in the heat conducting regions 10, the strength of connection between adjacent heat conducting regions 10 can be maintained even while unfilled layers are formed between the heat conducting regions 10.

In the low density sheet shown in FIG. 22, unfilled layers between heat conducting regions 10 appear in relative abundance. Specifically, lighter more highly deformable heat conducting sheet is obtained. While unfilled layers are formed in connecting regions 20, the layered structure of the heat conducting sheet is maintained by inter-layer connection due to resin material that partially fills between layers.

As described above, heat conducting sheet and the heat conducting sheet method of manufacture for embodiments of the present invention make it possible to provide heat conducting sheet with superior thermal conductivity as well as flexibility.

The heat conducting sheet and method of manufacture of the present invention can be used advantageously as electronic component heat sink sheet, etc. for a computer CPU, MPU (micro-processor unit), GPU, SoC, etc, as well as for light emitting elements such as LEDs, a liquid crystal display, PDP (plasma display panel), EL, and mobile phone applications. In automotive applications, it can be used advantageously as shock absorbing sheet (with dual purpose as heat sink sheet) between heat-generating components and heat sinks. Those heat-generating components include automobile headlights, power source battery blocks in electric vehicles such as electric automobiles and hybrid vehicles, (power) semiconductor driving elements, and MCUs (micro-controller units), etc.

1. A heat conducting sheet comprising:
a plurality of heat conducting regions with each region continuous between the two primary surfaces of the heat conducting sheet; and
connecting regions that connect adjacent surfaces of the plurality of heat conducting regions laterally stacked between the primary surfaces,
wherein the heat conducting sheet has an overall sheet or film structure,
wherein the heat conducting regions include vacancies,
wherein the connecting regions are made of materials that include flexible resin material formed in part with unfilled layers, and
wherein some of the resin material ingresses partially into the heat conducting region vacancies.

2. The heat conducting sheet as cited in claim 1 wherein the thermal conductivity that satisfies the relation 1.5≤λ_{0.8}/λ_{0.2}≤3.5, where λ_{0.2} W/m·K is heat conducting sheet thermal conductivity in the thickness direction when surface pressure of 0.2 N/mm² is applied in the thickness direction and λ_{0.8} W/m·K is heat conducting sheet thermal conductivity in the thickness direction when surface pressure of 0.8 N/mm² is applied in the thickness direction.

3. The heat conducting sheet as cited in claim 1 wherein the unfilled layers in the connecting regions occupy greater than or equal to 2% and less than or equal to 30% of the connecting region volume.

4. The heat conducting sheet as cited in claim 1 wherein the heat conducting regions are formed from materials including flake graphite and resin fiber.

5. The heat conducting sheet as cited in claim 4 wherein the resin fiber is aramid fiber.

6. The heat conducting sheet as cited in claim 4 wherein the graphite is expanded graphite.

7. The heat conducting sheet as cited in claim 1 wherein thermal conductivity in the thickness direction of the heat conducting sheet as measured by laser-flash method is greater than or equal to 10 W/m·K and less than or equal to 200 W/m·K.

8. The heat conducting sheet as cited in claim 1 wherein the heat conducting region width in the lateral direction of the heat conducting sheet is greater than or equal to 50 μm and less than or equal to 300 μm.

9. The heat conducting sheet as cited in claim 1 wherein the heat conducting sheet thickness is greater than or equal to 0.2 mm and less than or equal to 5 mm.

10. The heat conducting sheet as cited in claim 1 wherein the heat conducting sheet thickness is greater than or equal to 0.1 mm and less than or equal to 5 mm when 0.2 N/mm² surface pressure is applied in the thickness direction.

11. The heat conducting sheet as cited in claim 1 wherein the heat conducting sheet surface roughness Ra is greater than or equal to 0.1 μm and less than or equal to 100 μm.

12. The heat conducting sheet as cited in claim 1 wherein the resin material includes ring molecules, a first polymer with linear chain molecules that combine with multiple ring molecules by threading through the rings, polyrotaxane that is first polymer with blocking end groups at both ends of the first polymer, and a second polymer; and the polyrotaxane and second polymer are linked via the ring molecules.

13. The heat conducting sheet as cited in claim 1 wherein the angle between a normal to the surface of the heat conducting sheet and a normal to the heat conducting regions is greater than or equal to 25° and less than or equal to 90°.

14. The heat conducting sheet as cited in claim 1 wherein interfaces between the heat conducting regions and the connecting regions are formed as curved surfaces.

15. The heat conducting sheet as cited in claim 1 wherein the laterally stacked heat conducting regions and connecting regions have some variation in layer thickness.

16. A method of manufacturing a heat conducting sheet having a plurality of heat conducting regions stacked in the direction of the heat conducting sheet primary surfaces with each region established continuously from one primary surface to the other primary surface, the method comprising:
impregnating pre-form sheet that forms the heat conducting regions with uncured resin material;
rolling the uncured resin material impregnated pre-form sheet into a roll;
curing the uncured resin material with the sheet wound in roll form; and
cutting the rolled sheet with cured resin material along planes perpendicular to, parallel to, or on an incline to the axis of the roll.

17. The method as cited in claim 16 further comprising
preparing heat conducting region pre-form sheet as a wound roll prior to the step to impregnate heat conducting region pre-form sheet with uncured resin material.

18. The method as cited in claim 16 wherein the uncured resin is thermosetting resin.
